(19) United States
(12) Patent Application Publication
(10) Pub. No.: US 2026/0026195 A1
(43) Pub. Date: Jan. 22, 2026

(54) DISPLAY PANEL AND DISPLAY APPARATUS INCLUDING THE SAME

(71) Applicant: Samsung Display Co., Ltd., Yongin-si (KR)

(72) Inventors: Minsoo Kim, Yongin-si (KR); Jonghyun Choi, Yongin-si (KR)

(21) Appl. No.: 19/094,664

(22) Filed: Mar. 28, 2025

(30) Foreign Application Priority Data
Jul. 18, 2024 (KR) 10-2024-0095279

(51) Int. Cl. H10K 59/121; H10K 59/122; H10K 59/38; H10K 59/80

(52) U.S. Cl. CPC H10K 59/1213; H10K 59/122; H10K 59/38; H10K 59/873; H10K 59/878; H10K 59/879; H10K 59/8792

(57) ABSTRACT

A display panel includes a substrate, a pixel circuit including a thin-film transistor, a via layer above the pixel circuit, and defining a first opening, a pixel electrode inclined above the via layer, electrically connected to the pixel circuit, and having a portion in the first opening, a bank layer above the pixel electrode, and defining a second opening overlapping the first opening, a first reflective plate inclined above the bank layer, apart from the pixel electrode, facing the pixel electrode, and having a portion in the second opening, a high refractive index layer above the pixel electrode and the first reflective plate, and having a portion in the first and second openings, and an encapsulation layer above the high refractive index layer, wherein the high refractive index layer has a refractive index that is greater than a refractive index of the via layer or the encapsulation layer.

### CROSS-REFERENCE TO RELATED APPLICATION

The present application claims priority to, and the benefit of, Korean Patent Application No. 10-2024-0095279, filed on Jul. 18, 2024, in the Korean Intellectual Property Office, the entire disclosure of which is incorporated herein by reference.

### BACKGROUND

### 1. Field

One or more embodiments relate to a display panel, and a display apparatus including the same.

### 2. Description of the Related Art

Generally, display panels, such as organic light-emitting display panels, include thin-film transistors arranged in a display area to control the brightness of light-emitting diodes, etc. The thin-film transistors use a transmitted data signal, a driving voltage, and a common voltage to control corresponding light-emitting diodes to emit light of a corresponding color.

An electronic device may be a display apparatus including a display panel. The electronic device may include components arranged below the display panel. The components may include a sensor, a camera, etc. In addition, the components may emit and detect light, such as visible light and/or infrared light.

### SUMMARY

One or more embodiments include a display panel and a display apparatus that includes the same and is configured to emit light without separate wirings even in areas where components are arranged.

Embodiments set forth herein are examples, and embodiments of the disclosure are not limited thereto.

Additional aspects will be set forth in part in the description which follows and, in part, will be apparent from the description, or may be learned by practice of the presented embodiments of the disclosure.

According to one or more embodiments, a display panel includes a substrate, a pixel circuit above the substrate, and including a thin-film transistor, a via layer above the pixel circuit, and defining a first opening, a pixel electrode inclined above the via layer, electrically connected to the pixel circuit, and having at least a portion in the first opening, a bank layer above the pixel electrode, and defining a second opening overlapping the first opening, a first reflective plate inclined above the bank layer, apart from the pixel electrode, facing the pixel electrode, and having at least a portion in the second opening, a high refractive index layer above the pixel electrode and the first reflective plate, and having at least a portion in the first opening and in the second opening, and an encapsulation layer above the high refractive index layer, wherein the high refractive index layer has a refractive index that is greater than a refractive index of the via layer or the encapsulation layer.

The via layer may have an inclined surface defining the first opening, wherein the pixel electrode and the first reflective plate are above the inclined surface.

The pixel electrode may be apart from the pixel circuit in plan view.

The display panel may further include an anti-reflection layer above the encapsulation layer, and may include a light-blocking layer including a light-blocking material, and defining a third opening, and a color filter in the third opening.

The color filter may overlap the pixel electrode.

The light-blocking layer may overlap the pixel electrode.

The display panel may further include a second reflective plate above the via layer, and overlapping the light-blocking layer, and a third reflective plate above the high refractive index layer, and overlapping the light-blocking layer.

The display panel may further include a transflective plate inclined between the pixel electrode and the first reflective plate, having at least a portion in the first opening, and facing the pixel electrode.

The display panel may further include an intermediate layer above the pixel electrode, an opposite electrode above the intermediate layer, a first auxiliary layer above the via layer, extending from the opposite electrode, and including a transparent material, and a second auxiliary layer above the high refractive index layer, and including a transparent material.

The opposite electrode, the first auxiliary layer, and the second auxiliary layer may include a same material.

According to one or more embodiments, a display apparatus includes a display panel including a main display area, a component area, a substrate, a pixel circuit above the substrate, and including a thin-film transistor, a via layer above the pixel circuit, and defining a first opening, a pixel electrode inclined above the via layer, electrically connected to the pixel circuit, and having at least a portion in the first opening, a bank layer above the pixel electrode, and defining a second opening overlapping the first opening, a first reflective plate inclined above the bank layer, apart from the pixel electrode, having at least a portion in the second opening, facing the pixel electrode, and in the component area, a high refractive index layer above the pixel electrode and the first reflective plate, and having at least a portion in the first opening and in the second opening, and an encapsulation layer above the high refractive index layer, and a component below a back surface of the display panel, and overlapping the component area, wherein the high refractive index layer has a refractive index that is greater than a refractive index of the via layer or the encapsulation layer.

The via layer may have an inclined surface defining the first opening, wherein the pixel electrode and the first reflective plate are above the inclined surface.

The pixel electrode may be apart from the pixel circuit in plan view.

The display apparatus may further include an anti-reflection layer above the encapsulation layer, and may include a light-blocking layer including a light-blocking material, and defining a third opening, and a color filter in the third opening.

The color filter may overlap the pixel electrode.

The light-blocking layer may overlap the pixel electrode.

The display apparatus may further include a second reflective plate above the via layer, and overlapping the light-blocking layer, and a third reflective plate above the high refractive index layer, and overlapping the light-blocking layer.

The display apparatus may further include a transflective plate inclined between the pixel electrode and the first reflective plate, having at least a portion in the first opening, and facing the pixel electrode.

The display apparatus may further include an intermediate layer above the pixel electrode, an opposite electrode above the intermediate layer, a first auxiliary layer above the via layer, extending from the opposite electrode, and including a transparent material, and a second auxiliary layer above the high refractive index layer, and including a transparent material.

The opposite electrode, the first auxiliary layer, and the second auxiliary layer may include a same material.

According to one or more embodiments, an electronic device includes a display panel including a substrate, a pixel circuit above the substrate, and including a thin-film transistor, a via layer above the pixel circuit, and defining a first opening, a pixel electrode inclined above the via layer, electrically connected to the pixel circuit, and having at least a portion in the first opening, a bank layer above the pixel electrode, and defining a second opening overlapping the first opening, a first reflective plate inclined above the bank layer, apart from the pixel electrode, facing the pixel electrode, and having at least a portion in the second opening, a high refractive index layer above the pixel electrode and the first reflective plate, and having at least a portion in the first opening and in the second opening, and an encapsulation layer above the high refractive index layer, wherein the high refractive index layer has a refractive index that is greater than a refractive index of the via layer or the encapsulation layer.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

Aspects other than the above-described aspects will be apparent from a detailed description, the claims, and the drawings.

### BRIEF DESCRIPTION OF THE DRAWINGS

The above and other aspects of embodiments of the disclosure will be more apparent from the following description taken in conjunction with the accompanying drawings, in which:

FIG. 1 is a plan view schematically illustrating a display apparatus according to one or more embodiments;

FIG. 2 illustrates a display element and a pixel circuit connected thereto, which are provided in one pixel of a display apparatus according to one or more embodiments;

FIG. 3 is a cross-sectional view schematically illustrating a portion of the display apparatus of FIG. 1;

FIG. 4 is a cross-sectional view schematically illustrating a portion of a display panel of FIG. 3;

FIG. 5 is a cross-sectional view schematically illustrating a portion of the display panel of FIG. 3;

FIG. 6 is a cross-sectional view schematically illustrating a portion of the display panel of FIG. 3;

FIG. 7 is a cross-sectional view schematically illustrating a portion of the display panel of FIG. 3;

FIG. 8 is a cross-sectional view schematically illustrating a portion of the display panel of FIG. 3;

FIG. 9 is a cross-sectional view schematically illustrating a portion of the display panel of FIG. 3; and

FIG. 10 is a cross-sectional view schematically illustrating a portion of the display panel of FIG. 3;

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

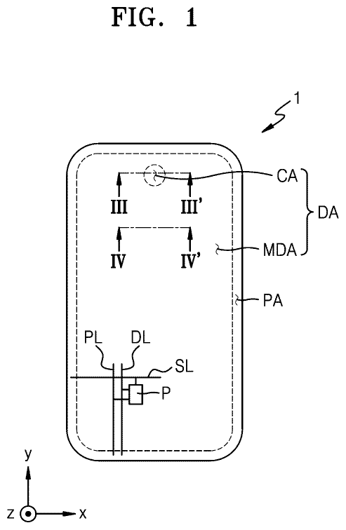

FIG. 1 is a plan view schematically illustrating a display apparatus 1 according to one or more embodiments.

The display apparatus 1 may be an electronic device, such as a smart phone, a mobile phone, a navigation device, a game console, a TV, a head unit for a vehicle, a notebook computer, a laptop computer, a tablet computer, a personal media player (PMP), or a personal digital assistant (PDA). In addition, the electronic device may be a flexible device.

The display apparatus 1 according to one or more embodiments is a device that displays a moving image and/or a still image. The display apparatus 1 may be applied to portable electronic devices such as mobile phones, smartphones, tablet personal computers (PCs), mobile communication terminals, electronic notebooks, electronic books, portable multimedia players (PMPs), navigations, and ultra-mobile PCs (UMPCs). For example, the display apparatus 1 may be applied to a display unit of a television, a laptop computer, a monitor, a billboard, or the Internet of Things (IoT). Alternatively, in one or more embodiments, the display apparatus 1 may be applied to a smartwatch, a watch phone, and/or a head-mounted display device (HMD) for implementing virtual reality and/or augmented reality.

The display apparatus 1 includes a display area DA, and a peripheral area PA outside the display area DA. In a plan view, the display area DA may have an approximately rectangular shape as shown in FIG. 1. However, the disclosure is not limited thereto, and the display area DA may have a polygonal shape, such as a triangle, a pentagon, or a hexagon, a circular shape, an oval shape, or an irregular shape. The corners of the edges of the display area DA may be rounded. The peripheral area PA may be a type of non-display area where display elements are not arranged. The peripheral area PA may entirely surround the display area DA.

The display apparatus 1 may provide a corresponding image according to light emitted from a plurality of pixels P arranged in the display area DA.

Each of the plurality of pixels P includes a display element, such as an organic light-emitting diode or an inorganic light-emitting diode, and may emit light of, for example, red, green, blue, or white. That is, each of the plurality of pixels P may be connected to a pixel circuit including a thin-film transistor, a storage capacitor, etc. The pixel circuit may be connected to a scan line SL, a data line DL crossing the scan line SL, and a driving voltage line PL. The scan line SL may extend in the x direction, and the data line DL and the driving voltage line PL may extend in the y direction.

During driving of the pixel circuit, each of the plurality of pixels P may emit light, and the display area DA provides a corresponding image through the light emitted from the plurality of pixels P. The plurality of the pixels P may be defined as an emission area that emits light of any one of red, green, blue, and white, as described above.

The peripheral area PA is an area where pixels P are not arranged, and does not provide an image. In the peripheral area PA, a built-in driving circuit for driving the pixels P, a power supply line, and a terminal portion, to which a printed circuit board including a driving circuit or a driver integrated circuit (IC) is connected, may be arranged.

The display area DA can include a main display area MDA and a component area CA. The main display area MDA may have a shape that surrounds the component area CA (e.g., in plan view). However, the disclosure is not limited thereto, and various modifications may be made, such as a part of the component area CA being in contact with the peripheral area PA. That is, the main display area MDA may at least partially surround the component area CA.

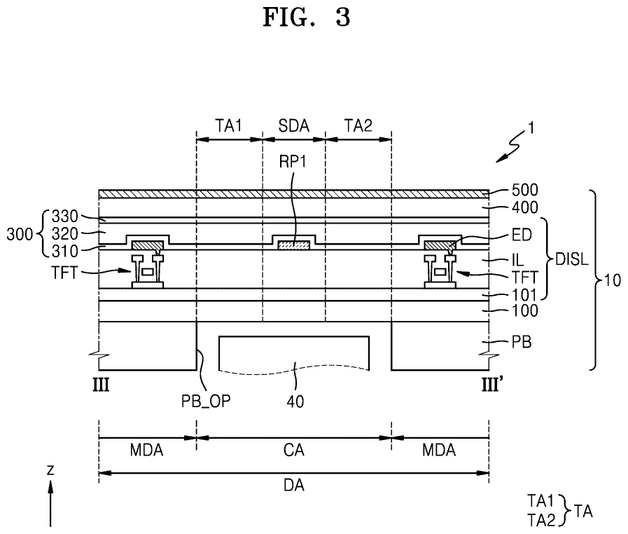

As described below with reference to FIG. 3, a component 40, which is an electronic element, may be arranged corresponding to the component area CA.

In a plan view (when viewed in a direction (the z direction) perpendicular to the display apparatus 1), the component area CA may have a polygonal shape, such as a triangle, a square, a pentagon, or a hexagon, a circular shape, an oval shape, a star shape, or an irregular shape.

Although it is illustrated in FIG. 1 that the display area DA includes one component area CA, the disclosure is not limited thereto. According to one or more other embodiments, the display apparatus 1 may include a plurality of component areas that are apart from each other. The sizes of the plurality of component areas may be different from each other, as may be suitable.

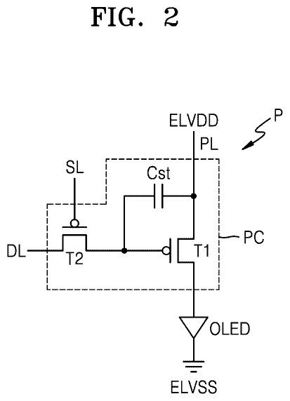

FIG. 2 illustrates a display element and a pixel circuit PC connected thereto, which are provided in one pixel P of a display apparatus according to one or more embodiments.

Referring to FIG. 2, an organic light-emitting diode OLED, which is the display element, is connected to the pixel circuit PC. The pixel circuit PC may include a first thin-film transistor T1, a second thin-film transistor T2, and a storage capacitor Cst. The organic light-emitting diode OLED may emit, for example, red, green, or blue light, or may emit red, green, blue, or white light.

The second thin-film transistor T2 is a switching thin-film transistor, is connected to the scan line SL and to the data line DL, and may be configured to transmit a data voltage input from the data line DL to the first thin-film transistor T1 according to a switching voltage input from the scan line SL. The storage capacitor Cst is connected to the second thin-film transistor T2 and to the driving voltage line PL, and may be configured to store a voltage corresponding to the difference between a voltage received from the second thin-film transistor T2 and a first power voltage ELVDD supplied to the driving voltage line PL.

The first thin-film transistor T1 is a driving thin-film transistor, is connected to the driving voltage line PL and to the storage capacitor Cst, and may be configured to control a driving current flowing through the organic light-emitting diode OLED from the driving voltage line PL in response to a voltage value stored in the storage capacitor Cst. The organic light-emitting diode OLED may be configured to emit light having a corresponding brightness by the driving current. An opposite electrode (e.g., a cathode) of the organic light-emitting diode OLED may be supplied with a second power voltage ELVSS.

Although FIG. 2 illustrates that the pixel circuit PC includes two thin-film transistors and one storage capacitor, it may be understood that in one or more other embodiments, the number of thin-film transistors or the number of storage capacitors may vary depending on the design of the pixel circuit PC.

FIG. 3 is a cross-sectional view schematically illustrating a portion of the display apparatus 1 of FIG. 1. For example, FIG. 3 may be a schematic cross-sectional view of the display apparatus 1 taken along the line III-III′ of FIG. 1.

Referring to FIG. 3, the display apparatus 1 may include a display panel 10, and a component 40 arranged to overlap the display panel 10. In one or more embodiments, a cover window may be arranged on the display panel 10 to protect the display panel 10.

A display area DA of the display panel 10 may include a component area CA and a main display area MDA. In the main display area MDA, a main image may be displayed, and in the component area CA, an auxiliary image may be displayed. The component 40 may be arranged under the display panel 10 to correspond to the component area CA. That is, in plan view (when viewed in a direction (the z direction) perpendicular to a substrate 100), the component area CA may overlap the component 40.

The component area CA may include a transmissive area TA through which light and/or sound, etc. output from the component 40 to the outside, or traveling toward the component 40 from the outside, may pass.

The component 40 may be an electronic element that uses light or sound. For example, the electronic element may be a proximity sensor that measures distance, a sensor that recognizes a part (e.g., fingerprint, iris, or face) of a user's body, a small lamp that outputs light, an illuminance sensor that measures brightness, or an image sensor (e.g., a camera) that captures an image. An electronic element that utilizes light may utilize light of various wavelength bands, such as visible light, infrared light, or ultraviolet light. An electronic element that utilizes sound may utilize sound of ultrasound or other frequency bands. In some embodiments, the component 40 may include sub-components, such as a light emitter and a light receiver. The component 40 may include a light emitter and a light receiver that are integrally formed as a single body, or may include a light emitter and a light receiver as a pair that are physically separated.

In the case of a display apparatus according to one or more embodiments, when light is transmitted through the component area CA, the light transmittance may be about 10% or more, about 20% or more, about 30% or more, about 40% or more, about 50% or more, about 60% or more, about 70% or more, about 75% or more, about 80% or more, about 85% or more, or about 90% or more.

The display panel 10 may include the substrate 100, a display layer DISL on the substrate 100, a touch layer 400, an anti-reflection layer 500, and a panel protection member PB arranged under the substrate 100.

The substrate 100 may include glass, metal, or a polymer resin. When the display panel 10 is flexible or bendable, the substrate 100 may include a polymer resin, such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may be modified in various ways. For example, the substrate 100 may have a multi-layer structure including two layers including the polymer resin, and a barrier layer including an inorganic material (e.g., silicon oxide, silicon nitride, or silicon oxynitride) interposed between the two layers.

The display layer DISL may include a pixel circuit including thin-film transistors TFT, a light-emitting element ED as a display element, and an encapsulation layer 300. It is illustrated in FIG. 3 that the display layer DISL includes a buffer layer 101, and a thin-film transistor TFT and the like are arranged on the buffer layer 101. The light-emitting element ED may be an organic light-emitting diode OLED. The pixel circuit including the thin-film transistor TFT may control whether or not the light-emitting element ED emits light, or may control the level of light emission. An insulating layer IL for insulation between the active layer, gate electrode, and/or source/drain electrodes of the thin-film transistor TFT may also be included in the display layer DISL.

The component area CA may include a sub-display area SDA that receives light from an adjacent light-emitting element ED arranged in the main display area MDA, and that emits the light to the outside. That is, the component area CA may include the sub-display area SDA and the transmissive area TA, and a first reflective plate RP1 may be arranged in the sub-display area SDA. The transmissive area TA may be defined as an area in the component area CA where the first reflective plate RP1 is not arranged. The transmissive area TA may be an area through which light/signal emitted from the component 40 arranged corresponding to the component area CA, or through which light/signal incident on the component 40 is transmitted.

A plurality of transmissive areas TA may be provided. For example, the transmissive area TA may include a first transmissive area TA1 and a second transmissive area TA2. The first transmissive area TA1, the sub-display area SDA, and the second transmissive area TA2 may be sequentially arranged. That is, the sub-display area SDA may be arranged between the first transmissive area TA1 and the second transmissive area TA2.

However, this is an example, and the number and arrangement of transmissive areas TA and sub-display areas SDA are not limited thereto. For example, three transmissive areas TA may be provided, and two sub-display areas SDA may be provided.

The display elements, such as the light-emitting element ED, may be covered with the encapsulation layer 300, as illustrated in FIG. 3. Alternatively, the display elements may be covered with a sealing substrate. The encapsulation layer 300 may include at least one inorganic encapsulation layer and at least one organic encapsulation layer, as illustrated in FIG. 3. For example, the encapsulation layer 300 may include a first inorganic encapsulation layer 310, a second inorganic encapsulation layer 330, and an organic encapsulation layer 320 therebetween.

The first inorganic encapsulation layer 310 and the second inorganic encapsulation layer 330 may each include one or more inorganic insulating materials, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The organic encapsulation layer 320 may include a polymer-based material. The polymer-based material may include a silicon-based resin, an acrylic-based resin (e.g., polymethyl methacrylate or polyacrylic acid), an epoxy-based resin, polyimide, polyethylene, or the like.

Each of the first inorganic encapsulation layer 310, the organic encapsulation layer 320, and the second inorganic encapsulation layer 330 may be integrally formed to cover the main display area MDA and the component area CA.

The touch layer 400 may obtain coordinate information according to an external input, for example, a touch event. The touch layer 400 may include a touch electrode, and touch wiring lines connected to the touch electrode. The touch layer 400 may detect an external input by using a self-capacitance method or a mutual capacitance method.

The touch layer 400 may be formed on the encapsulation layer 300. Alternatively, the touch layer 400 may be formed separately on a touch substrate, and may be placed on the encapsulation layer 300 through an adhesive layer, such as an optically clear adhesive (OCA). In one or more embodiments, the touch layer 400 may be formed directly on the encapsulation layer 300, in which case the adhesive layer may not be arranged between the touch layer 400 and the encapsulation layer 300.

The anti-reflection layer 500 may reduce the degree to which light (external light) incident from the outside toward the display apparatus 1 is reflected by the display apparatus 1. The anti-reflection layer 500 may include a light-blocking layer and color filters, and may also include an overcoat layer if suitable. A detailed configuration of the anti-reflection layer 500 is described below.

In one or more embodiments, a cover window may be arranged above the display panel 10, that is, above the anti-reflection layer 500, to protect the display panel 10. The cover window may be combined with the anti-reflection layer 500 through an adhesive layer, such as an OCA. The cover window may include a glass material or a plastic material. The glass material may include an ultra-thin glass. The plastic material may include polyethersulphone, polyacrylate, polyetherimide, polyethylene naphthalate, polyethylene terephthalate, polyphenylene sulfide, polyarylate, polyimide, polycarbonate, cellulose acetate propionate, or the like.

The panel protection member PB may be attached to a lower portion of the substrate 100, and may support and protect the substrate 100. The panel protection member PB may have an opening PB_OP corresponding to the component area CA. By making the panel protection member PB have the opening PB_OP, the light transmittance of the component area CA may be improved. The panel protection member PB may include polyethyleneterephthalate or polyimide.

The area of the component area CA may be larger than the area in which the component 40 is arranged. Accordingly, the area of the opening PB_OP provided in the panel protection member PB may not match the area of the component area CA. Although FIG. 3 illustrates that at least a portion of the component 40 is inserted into the opening PB_OP provided in the panel protection member PB, the component 40 may be arranged apart from the display panel 10.

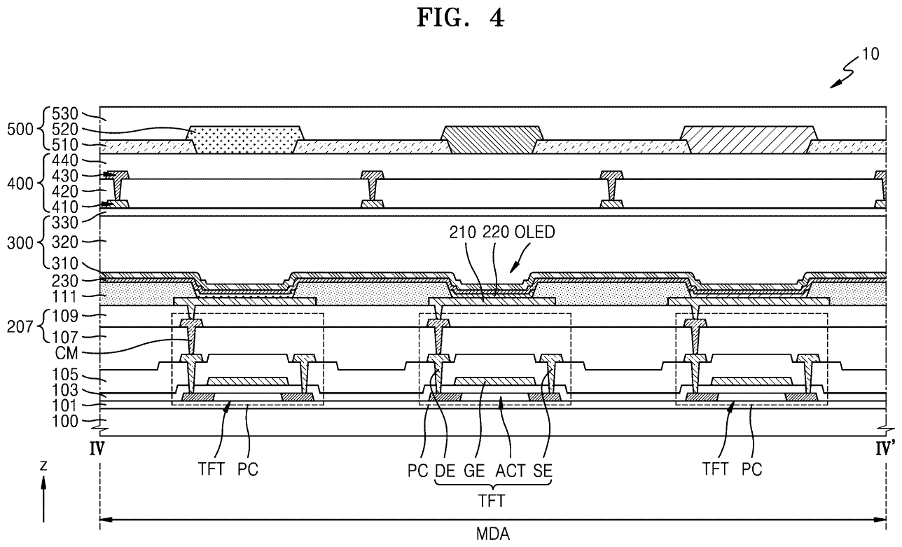

FIG. 4 is a cross-sectional view schematically illustrating a portion of the display panel 10 of FIG. 3. For example, FIG. 4 is a cross-sectional view of the display apparatus 1 taken along the line IV-IV′ of FIG. 1. Alternatively, FIG. 4 is a cross-sectional view of the main display area MDA of the display apparatus 1 of FIG. 1.

Referring to FIG. 4, a plurality of organic light-emitting diodes OLED and a pixel circuit PC corresponding to each organic light-emitting diode OLED may be arranged in the main display area MDA. Each pixel circuit PC may include a thin-film transistor TFT electrically connected to the organic light-emitting diode OLED.

Each organic light-emitting diode OLED may emit light of a different respective color. In one or more embodiments, each organic light-emitting diode OLED may emit red light, green light, or blue light. In one or more other embodiments, each organic light-emitting diode OLED may emit red light, green light, blue light, or white light. One subpixel may include one organic light-emitting diode OLED and a thin-film transistor TFT corresponding thereto. A pixel may include, for example, three subpixels, each emitting red light, green light, or blue light. The intensity of the red light, green light, or blue light emitted from each subpixel may be adjusted to adjust the color of light emitted from the pixel.

The substrate 100 may include a polymer resin and/or an inorganic insulating material. The polymer resin may include polyethersulphone, polyacrylate, polyetherimide, polyethylene naphthalate, polyethylene terephthalate, polyphenylene sulfide, polyarylate, polyimide, polycarbonate, cellulose acetate propionate, or the like. The inorganic insulating material may include silicon oxide (SiOₓ), silicon nitride (SiNₓ), and/or silicon oxynitride (SiON). The layer structure of the substrate 100 may be variously modified, and the substrate 100 may have a single-layer structure including glass or metal.

A buffer layer 101 may be arranged on the substrate 100 (as used herein, “arranged on” may mean “above”). The buffer layer 101 may prevent or reduce the penetration of foreign materials, moisture, or external air from a lower portion of the substrate 100. The buffer layer 101 may include an inorganic insulating material, such as silicon oxide (SiOₓ), silicon nitride (SiNₓ), and/or silicon oxynitride (SiON), and may have a single-layer structure or a multi-layer structure including the inorganic insulating material.

Each organic light-emitting diode OLED may be electrically connected to a pixel circuit PC corresponding thereto. Each organic light-emitting diode OLED may be electrically connected to a pixel circuit PC between the substrate 100 and the organic light-emitting diode OLED.

In one or more embodiments, the pixel circuit PC may include a thin-film transistor TFT and a capacitor, and may also include a plurality of wiring lines connected thereto as suitable. The thin-film transistor TFT may include an active layer ACT, a gate electrode GE overlapping a channel region of the active layer ACT, a source electrode SE connected to a source region of the active layer ACT, and a drain electrode DE connected to a drain region of the active layer ACT. In this case, the source electrode SE and the drain electrode DE may be defined as parts of wiring lines that contact the active layer ACT. In addition, when the active layer ACT of one thin-film transistor TFT and the active layer ACT of another thin-film transistor TFT are directly connected to each other, the thin-film transistors TFT may not have the source electrode SE and/or the drain electrode DE.

A gate-insulating layer 103 may be arranged between the active layer ACT and the gate electrode GE, and an interlayer insulating layer 105 may be arranged between the gate electrode GE and the source electrode SE, and between the gate electrode GE and the drain electrode DE. A via layer 207 may be arranged on the source electrode SE and on the drain electrode DE.

The active layer ACT may include polysilicon. In some embodiments, the active layer ACT may include amorphous silicon. In some embodiments, the active layer ACT may include an oxide semiconductor of at least one material selected from indium (In), gallium (Ga), stannum (Sn), zirconium (Zr), vanadium (V), hafnium (Hf), cadmium (Cd), germanium (Ge), chromium (Cr), titanium (Ti), and/or zinc (Zn). The active layer ACT may include a channel region, and a source region and a drain region doped with impurities.

The gate electrode GE may include a low resistance conductive material, such as molybdenum (Mo), aluminum (Al), copper (Cu), and/or titanium (Ti), and may have a single-layer structure or a multi-layer structure including the low resistance conductive material.

The source electrode SE and/or the drain electrode DE may include aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), and/or copper (Cu), and may have a single-layer structure or a multi-layer structure including the aforementioned material.

The gate-insulating layer 103 and/or the interlayer insulating layer 105 may each include an inorganic insulating material, such as silicon oxide (SiOₓ), silicon nitride (SiNₓ), and/or silicon oxynitride (SiON), and may have a single-layer structure or a multi-layer structure including the aforementioned material.

The via layer 207 may be arranged on the interlayer insulating layer 105. The via layer 207 may include an organic material, such as acrylic, benzocyclobutene (BCB), polyimide, or hexamethyldisiloxane (HMDSO). The via layer 207 may function as a protective film covering the thin-film transistor TFT, and an upper portion of the via layer 207 may be flat.

For example, a plurality of via layers 207 may be provided. For example, as illustrated in FIG. 4, the plurality of via layers 207 may include a first via layer 107 and a second via layer 109. The second via layer 109 may be arranged on the first via layer 107. For example, the plurality of via layers 207 may include the same material. However, unlike as illustrated in FIG. 4, the display panel 10 may include a single layer or three or more layers.

A connection electrode CM may be arranged between the first via layer 107 and the second via layer 109. The thin-film transistor TFT may be electrically connected to a pixel electrode 210 of a corresponding organic light-emitting diode OLED through the connection electrode CM. The connection electrode CM may be connected to the thin-film transistor TFT through a contact hole of the first via layer 107, and the pixel electrode 210 may be connected to the connection electrode CM through a contact hole of the second via layer 109.

Each organic light-emitting diode OLED may include an overlapping structure in which the pixel electrode 210, an intermediate layer 220, and an opposite electrode 230 overlap one another. The overlapping structure may include various functional layers. The pixel electrodes 210 of the organic light-emitting diodes OLED may be apart from each other.

The pixel electrode 210 may be located above the second via layer 109. The pixel electrode 210 may include a reflective film including silver (Ag), magnesium (Mg), aluminum (AI), platinum (Pt), palladium (Pd), gold (Au), nickel (Ni), neodymium (Nd), iridium (Ir), chromium (Cr), or a compound thereof. The pixel electrode 210 may include a reflective film including the aforementioned material, and a transparent conductive film arranged above or/and below the reflective film. The transparent conductive film may include indium tin oxide (ITO), indium zinc oxide (IZO), zinc oxide (ZnO), indium oxide (In₂O₃), indium gallium oxide (IGO), aluminum zinc oxide (AZO), or the like.

A bank layer 111 covering the edge of the pixel electrode 210 may have, or define, an opening overlapping the center of the pixel electrode 210. The opening of the bank layer 111 may define an emission area of the organic light-emitting diode OLED. For example, the width of the opening of the bank layer 111 may correspond to the width of the emission area of the organic light-emitting diode OLED.

The bank layer 111 may include a light-blocking insulating material. Accordingly, the bank layer 111 may be a colored, opaque, and light-blocking insulating layer and may appear black. For example, the bank layer 111 may include a polyimide (PI)-based binder and a pigment mixed with red, green, and blue. Alternatively, the bank layer 111 may include a cardo-based binder resin and a mixture of a lactam black pigment and a blue pigment. Alternatively, the bank layer 111 may include carbon black. The bank layer 111 may reduce or prevent reflection of external light together with the anti-reflection layer 500 to be described below, and may improve the contrast of the display panel 10.

The intermediate layer 220 may be located corresponding to each opening of the bank layer 111, and may overlap the pixel electrode 210. The intermediate layer 220 may include an emission layer including a high molecular organic material or a low molecular organic material that emits light of a corresponding color corresponding to each subpixel. The intermediate layer 220 may include functional layers arranged below and/or above the emission layer.

In one or more embodiments, the functional layers may include a hole transport layer (HTL) and/or a hole injection layer (HIL). In one or more embodiments, the functional layers may include an electron transport layer (ETL) and/or an electron injection layer (EIL). In one or more embodiments, each of the functional layers may be integrally formed as a single body with respect to multiple pixels, unlike as illustrated in FIG. 4.

The opposite electrode 230 may cover the intermediate layer 220 and the bank layer 111. In one or more embodiments, the opposite electrode 230 may be integrally formed as a single body with respect to multiple pixels.

The encapsulation layer 300 may cover the organic light-emitting diode OLED. In one or more embodiments, the encapsulation layer 300 may be arranged on the opposite electrode 230. The encapsulation layer 300 may include a first inorganic encapsulation layer 310, a second inorganic encapsulation layer 330, and an organic encapsulation layer 320 therebetween.

Each of the first inorganic encapsulation layer 310 and the second inorganic encapsulation layer 330 may include one or more inorganic insulating materials. The inorganic insulating materials may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ).

The organic encapsulation layer 320 may include a polymer-based material. The polymer-based material may include an acrylic resin, an epoxy resin, polyimide, and/or polyethylene. For example, the organic encapsulating layer 320 may include an acrylic resin, such as polymethyl methacrylate and/or polyacrylic acid. The organic encapsulating layer 320 may be formed by curing a monomer or by applying a polymer.

The touch layer 400 may include touch electrodes, and the touch electrodes may have a mesh structure that at least partially surrounds the emission area of each organic light-emitting diode OLED in plan view.

The touch layer 400 may include a first touch electrode layer 410 on the encapsulating layer 300, a first touch-insulating layer 420 on the first touch electrode layer 410, a second touch electrode layer 430 on the first touch-insulating layer 420, and a second touch-insulating layer 440 on the second touch electrode layer 430. The first touch electrode layer 410 and the second touch electrode layer 430 may be connected to each other through a contact hole formed in the first touch-insulating layer 420. In one or more embodiments, the first touch electrode layer 410 may be arranged on the second inorganic encapsulation layer 330, as illustrated in FIG. 4. In one or more other embodiments, an additional touch-insulating layer may be arranged between the first touch electrode layer 410 and the second inorganic encapsulation layer 330. The first touch-insulating layer 420 and the second touch-insulating layer 440 may each include an inorganic insulating material and/or an organic insulating material.

The anti-reflection layer 500 may be arranged on the touch layer 400. The anti-reflection layer 500 may include a light-blocking layer 510, color filters 520, and an overcoat layer 530. The light-blocking layer 510 may include a mesh structure surrounding the emission area of each organic light-emitting diode OLED in plan view. The light-blocking layer 510 may include a light-blocking material, and may be recognized as an opaque color, for example, black. In one or more embodiments, the light-blocking layer 510 may be a black matrix. The light-blocking layer 510 may reduce or prevent reflection of external light. In addition, the light-blocking layer 510 may cover a touch electrode layer, for example, the second touch electrode layer 430, arranged underneath the light-blocking layer 510, so that the touch electrode layer is not recognized by a user. Each of the color filters 520 may be arranged in an opening of the light-blocking layer 510 corresponding to each organic light-emitting diode OLED. The color filter 520 may transmit light of the same color as light emitted from an organic light-emitting diode OLED corresponding thereto. Through the light-blocking layer 510 and the color filters 520, the anti-reflection layer 500 may improve the contrast of the display panel 10 and, by extension, the display apparatus. The overcoat layer 530 may be arranged on the light-blocking layer 510 and the color filters 520. The overcoat layer 530 may entirely cover the light-blocking layer 510 and the color filters 520.

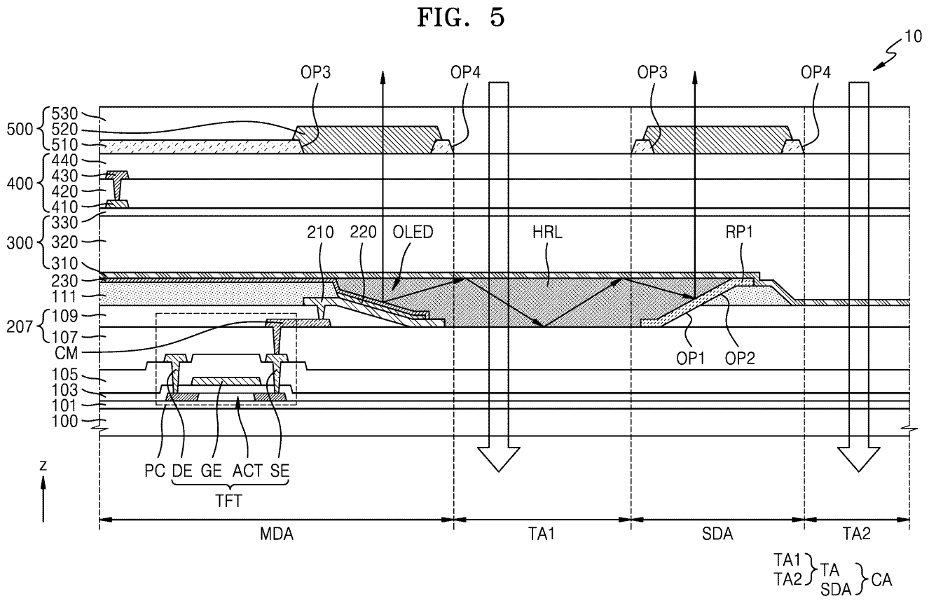

FIG. 5 is a cross-sectional view schematically illustrating a portion of the display panel 10 of FIG. 3. For example, FIG. 5 is an enlarged view of a portion of FIG. 3. Alternatively, FIG. 5 is a cross-sectional view illustrating the main display area MDA and the component area CA of the display apparatus 1 of FIG. 1.

In FIG. 5, the same reference numerals as those in FIG. 4 indicate the same members as those in FIG. 4, and thus, redundant descriptions thereof are omitted.

Referring to FIG. 5, an organic light-emitting diode OLED, and a pixel circuit PC corresponding to the organic light-emitting diode OLED, may be arranged in the main display area MDA. The pixel circuit PC may include a thin-film transistor TFT electrically connected to the organic light-emitting diode OLED.

A buffer layer 101 may be arranged on the substrate 100. The pixel circuit PC may be arranged on the buffer layer 101. That is, the pixel circuit PC including the thin-film transistor TFT may be arranged on the substrate 100.

The organic light-emitting diode OLED may be electrically connected to the pixel circuit PC. The organic light-emitting diode OLED may be electrically connected to the pixel circuit PC between the substrate 100 and the organic light-emitting diode OLED.

The thin-film transistor TFT may include an active layer ACT, a gate electrode GE overlapping a channel region of the active layer ACT, a source electrode SE connected to a source region of the active layer ACT, and a drain electrode DE connected to a drain region of the active layer ACT.

A gate-insulating layer 103 may be arranged between the active layer ACT and the gate electrode GE, and an interlayer insulating layer 105 may be arranged between the gate electrode GE and the source electrode SE, and between the gate electrode GE and the drain electrode DE. A via layer 207 may be arranged on the source electrode SE and on the drain electrode DE.

The via layer 207 may be arranged on the interlayer insulating layer 105. That is, the via layer 207 may be arranged on a pixel circuit PC. For example, a plurality of via layers 207 may be provided. For example, the plurality of via layers 207 may include a first via layer 107, and a second via layer 109 arranged on the first via layer 107.

A connection electrode CM may be arranged between the first via layer 107 and the second via layer 109. The thin-film transistor TFT may be electrically connected to a pixel electrode 210 of a corresponding organic light-emitting diode OLED through the connection electrode CM. The connection electrode CM may be connected to the thin-film transistor TFT through a contact hole of the first via layer 107, and the pixel electrode 210 may be connected to the connection electrode CM through a contact hole of the second via layer 109.

The via layer 207 may have/define a first opening OP1. The first opening OP1 may be sunken from the upper surface of the via layer 207. For example, the first opening OP1 may pass through the second via layer 109, and may not pass through the first via layer 107. The depth of the first opening OP1 may be the same as the height of the second via layer 109.

In a plan view, the first opening OP1 may overlap the main display area MDA and the component area CA. For example, in plan view, the first opening OP1 may overlap the main display area MDA, the transmissive area TA (e.g., the first transmissive area TA1), and the sub-display area SDA (e.g., may overlap respective portions thereof).

The inner surface of the via layer 207 forming, or defining, the first opening OP1 may be inclined. The via layer 207 may have an inclined surface forming, or defining, the first opening OP1. For example, the end of the second via layer 109 defining the first opening OP1 may be inclined. The first opening OP1 may gradually increase in width in a direction (e.g., the +z-axis direction) away from the substrate 100.

The organic light-emitting diode OLED may include an overlapping structure in which the pixel electrode 210, the intermediate layer 220, and the opposite electrode 230 overlap one another. The overlapping structure may include various functional layers.

The pixel electrode 210 may be arranged on the via layer 207, and may be electrically connected to the pixel circuit PC, as described above. At least a portion of the pixel electrode 210 may be accommodated in the first opening OP1. The pixel electrode 210 may be arranged on an inclined surface of the via layer 207 defining the first opening OP1.

The pixel electrode 210 may be arranged on the second via layer 109. In one or more embodiments, at least a portion of the pixel electrode 210 may be in contact with the first via layer 107.

The bank layer 111 may be arranged on the pixel electrode 210, and may define a second opening OP2. The bank layer 111 may be arranged on the via layer 207, and may cover an end of the pixel electrode 210. One end of the pixel electrode 210 may be sealed by the bank layer 111, and the other end of the pixel electrode 210 may be exposed from the bank layer 111. For example, the bank layer 111 may be arranged on the second via layer 109.

The second opening OP2 may overlap the first opening OP1. In a plan view, the second opening OP2 may overlap the main display area MDA and the component area CA. For example, in plan view, the second opening OP2 may overlap the main display area MDA, the transmissive area TA (e.g., the first transmissive area TA1), and the sub-display area SDA (e.g., may overlap respective portions thereof).

The inner surface of the bank layer 111 forming/defining the second opening OP2 may be inclined. The bank layer 111 may have an inclined surface defining the second opening OP2. The second opening OP2 may gradually increase in width in the direction (e.g., the +z-axis direction) away from the substrate 100.

The intermediate layer 220 may be arranged on the pixel electrode 210. The intermediate layer 220 may be accommodated in the first opening and in the second opening OP2. One end of the intermediate layer 220 may be in contact with the bank layer 111.

The intermediate layer 220 may include an emission layer including a high molecular organic material or a low molecular organic material that emits light of a corresponding color. The intermediate layer 220 may include functional layers arranged below and/or above the emission layer.

In one or more embodiments, the functional layers may include an HTL and/or an HIL. In one or more embodiments, the functional layers may include an ETL and/or an EIL. In one or more embodiments, each of the functional layers may be integrally formed as a single body with respect to multiple pixels, unlike as illustrated in FIG. 5.

The opposite electrode 230 may be arranged on the intermediate layer 220. The opposite electrode 230 may cover the intermediate layer 220 and the bank layer 111. In one or more embodiments, one end of the opposite electrode 230 may be arranged on the pixel electrode 210. In one or more embodiments, the opposite electrode 230 may overlap the main display area MDA. In one or more embodiments, the opposite electrode 230 may not overlap the component area CA (e.g., may be separated from the component area CA in plan view).

For example, the pixel circuit PC, the connection electrode CM, and the pixel electrode 210 may be sequentially arranged in a direction (e.g., a rightward direction) from the main display area MDA toward the component area CA. The connection electrode CM may electrically connect the source electrode SE to the pixel electrode 210. In this structure, the pixel electrode 210 may be apart from the pixel circuit PC in plan view.

Because the inner surface of the via layer 207 defining the first opening OP1 is inclined, at least a portion of the pixel electrode 210 arranged on the via layer 207 may be inclined. The pixel electrode 210 may be arranged on the inclined surface of the via layer 207. The pixel electrode 210, which is arranged on the inner surface of the via layer 207 defining the first opening OP1, may include an inclined surface.

Similarly, at least a portion of the intermediate layer 220 arranged on the pixel electrode 210 may be inclined. The intermediate layer 220 arranged on the inclined surface of the pixel electrode 210 may have an inclined surface. In addition, at least a portion of the opposite electrode 230 arranged on the intermediate layer 220 may be inclined. The opposite electrode 230 overlapping the inclined surface of the pixel electrode 210 may have an inclined surface.

The first reflective plate RP1 may be arranged on the bank layer 111 to be apart from the pixel electrode 210. At least a portion of the first reflective plate RP1 may be accommodated in the second opening OP2. The first reflective plate RP1 may be in contact with the via layer 207 (e.g., the second via layer 109) and with the bank layer 111. The first reflective plate RP1 may be accommodated in each of the first opening OP1 and the second opening OP2.

Because the inner surface of the via layer 207 defining the first opening OP1, and the inner surface of the bank layer 111 defining the second opening OP2, are inclined, at least a portion of the first reflective plate RP1 arranged on the via layer 207 and the bank layer 111 may be inclined. The first reflective plate RP1 may be arranged on the inclined surface of the via layer 207. The first reflective plate RP1 arranged on the inner surface of the via layer 207 defining the first opening OP1 may have an inclined surface. In addition, the first reflective plate RP1 arranged on the inner surface of the bank layer 111 defining the second opening OP2 may have an inclined surface. In this case, the inclined surface of the second opening OP2 and the inclined surface of the bank layer 111 may form the same plane, or may be the same.

The first reflective plate RP1 may include the same material as the pixel electrode 210. For example, the first reflective plate RP1 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. However, this is an example, and the material of the first reflective plate RP1 is not limited thereto.

The pixel circuit PC and the organic light-emitting diode OLED may each be arranged in the main display area MDA. That is, in plan view, the pixel circuit PC and the organic light-emitting diode OLED may each overlap the main display area MDA.

The first reflective plate RP1 may be arranged in the sub-display area SDA. That is, in plan view, the first reflective plate RP1 may overlap the sub-display area SDA.

The organic light-emitting diode OLED and the first reflective plate RP1 may be apart from each other with the transmissive area TA therebetween. For example, as illustrated in FIG. 5, the organic light-emitting diode OLED and the first reflective plate RP1 may be apart from each other with the first transmissive area TA1 therebetween.

The pixel electrode 210 and the first reflective plate RP1 may be inclined to face each other. Therefore, the intermediate layer 220 and the first reflective plate RP1 arranged on the pixel electrode 210 may also be inclined to face each other. That is, the distance between the pixel electrode 210 and the first reflective plate RP1 may gradually increase in a direction (e.g., the +z-axis direction) away from the substrate 100.

A high refractive index layer HRL may be arranged on and between the pixel electrode 210 and the first reflective plate RP1. At least a portion of the high refractive index layer HRL may be accommodated in the first opening OP1 and in the second opening OP2. The high refractive index layer HRL may be arranged between the organic light-emitting diode OLED and the first reflective plate RP1, and may fill the first opening OP1 and the second opening OP2. A portion of the high refractive index layer HRL arranged in the main display area MDA may cover the opposite electrode 230 and the pixel electrode 210. A portion of the high refractive index layer HRL arranged in the transmissive area TA (e.g., the first transmissive area TA1) may be arranged on the via layer 207. A portion of the high refractive index layer HRL arranged in the sub-display area SDA may be arranged on the first reflective plate RP1.

The high refractive index layer HRL may have a higher refractive index than the via layer 207 (e.g., the first via layer 107) and the encapsulation layer 300 (e.g., the first inorganic encapsulation layer 310) described below. For example, the high refractive index layer HRL may include an organic insulating material. Although it is illustrated in FIG. 5 that the high refractive index layer HRL is a single layer, the high refractive index layer HRL may include a plurality of layers, in one or more embodiments. For example, the high refractive index layer HRL may have a structure in which a plurality of layers are stacked.

The encapsulation layer 300 may be arranged on the high refractive index layer HRL. The encapsulation layer 300 may cover the opposite electrode 230, the high refractive index layer HRL, the bank layer 111, and the via layer 207. The encapsulation layer 300 may include a first inorganic encapsulation layer 310, a second inorganic encapsulation layer 330, and an organic encapsulation layer 320 therebetween.

The touch layer 400 may include touch electrodes, and the touch electrodes may have a mesh structure that at least partially surrounds the emission area of each organic light-emitting diode OLED in plan view. The touch layer 400 may include a first touch electrode layer 410 on the encapsulating layer 300, a first touch-insulating layer 420 on the first touch electrode layer 410, a second touch electrode layer 430 on the first touch-insulating layer 420, and a second touch-insulating layer 440 on the second touch electrode layer 430.

The anti-reflection layer 500 may be arranged on the touch layer 400. That is, the anti-reflection layer 500 may be arranged on the encapsulation layer 300. The anti-reflection layer 500 may include a light-blocking layer 510, color filters 520, and an overcoat layer 530.

The light-blocking layer 510 may include a light-blocking material, and may define a third opening OP3 and a fourth opening OP4. The color filter 520 may be accommodated in the third opening OP3. The color filter 520 may be omitted from the fourth opening OP4. The overcoat layer 530 may be arranged on the light-blocking layer 510 and on the color filter 520. At least a portion of the overcoat layer 530 may be accommodated in the fourth opening OP4.

A plurality of third openings OP3 may be provided. The plurality of third openings OP3 may be arranged in the main display area MDA and in the sub-display area SDA. In a plan view, at least one of the third openings OP3 may overlap the organic light-emitting diode OLED. In addition, at least one of the third openings OP3 may overlap the first reflective plate RP1 in plan view.

In this structure, a plurality of color filters 520 may be provided. The plurality of color filters 520 may be arranged in the main display area MDA and in the sub-display area SDA. The color filters 520 may overlap the pixel electrode 210. In a plan view, at least one of the color filters 520 may overlap the organic light-emitting diode OLED. In addition, in plan view, at least one of the color filters 520 may overlap the first reflective plate RP1.

The fourth opening OP4 may be arranged in the transmissive area TA. In a plan view, the fourth opening OP4 may not overlap (e.g., may be separated from, in plan view) each of the organic light-emitting diode OLED and the first reflective plate RP1. For example, a plurality of fourth openings OP4 may be provided. The plurality of fourth openings OP4 may be arranged in the first transmissive area TA1 and in the second transmissive area TA2.

At least a portion of the light emitted from the organic light-emitting diode OLED may be emitted outside the display panel 10 through the third opening OP3 and through the color filter 520. Therefore, a user may recognize the light in the main display area MDA.

Because the high refractive index layer HRL has a higher refractive index than the encapsulation layer 300 (e.g., than the first inorganic encapsulation layer 310), light passing through the inside of the high refractive index layer HRL may be totally reflected at the boundary between the high refractive index layer HRL and the encapsulation layer 300 (as used herein, “totally reflected” may mean “substantially totally reflected”). Because the high refractive index layer HRL has a higher refractive index than the via layer 207 (e.g., the first via layer 107), light passing through the inside of the high refractive index layer HRL may be totally (e.g., substantially) reflected at the boundary between the high refractive index layer HRL and the via layer 207.

At least a portion of the light emitted from the organic light-emitting diode OLED may be substantially totally reflected at the boundary between the high refractive index layer HRL and the encapsulation layer 300, and at the boundary between the high refractive index layer HRL and the via layer 207, and may be transmitted to the first reflective plate RP1. At least a portion of the light transmitted to the first reflective plate RP1 may be reflected by the first reflective plate RP1, and may be emitted to the outside through the third opening OP3 and through the color filter 520. That is, the high refractive index layer HRL may guide at least a portion of the light emitted from the organic light-emitting diode OLED. Therefore, the user may view the light in the sub-display area SDA.

In this case, due to the substantial total reflection phenomenon of light, energy loss may be reduced in the process of transmitting the light emitted from the organic light-emitting diode OLED to the first reflective plate RP1. Therefore, the brightness of the display panel 10 in the sub-display area SDA may be improved.

In this structure, a separate wiring line connecting the main display area MDA to the sub-display area SDA may not be arranged in (e.g., may be omitted from) the transmissive area (e.g., the first transmissive area TA1). Therefore, light/signal emitted from the component 40 (see FIG. 3), or light/signal incident on the component 40, may pass through the transmissive area TA without being obstructed by a separate wiring line. Accordingly, the performance of the component 40 may be improved.

In one or more embodiments, the color filter 520 arranged in the sub-display area SDA may include a quantum dot color filter having the same color as the organic light-emitting diode OLED arranged in the main display area MDA. Therefore, the amount of light reflected from the first reflective plate RP1 and passing through the color filter 520 may increase.

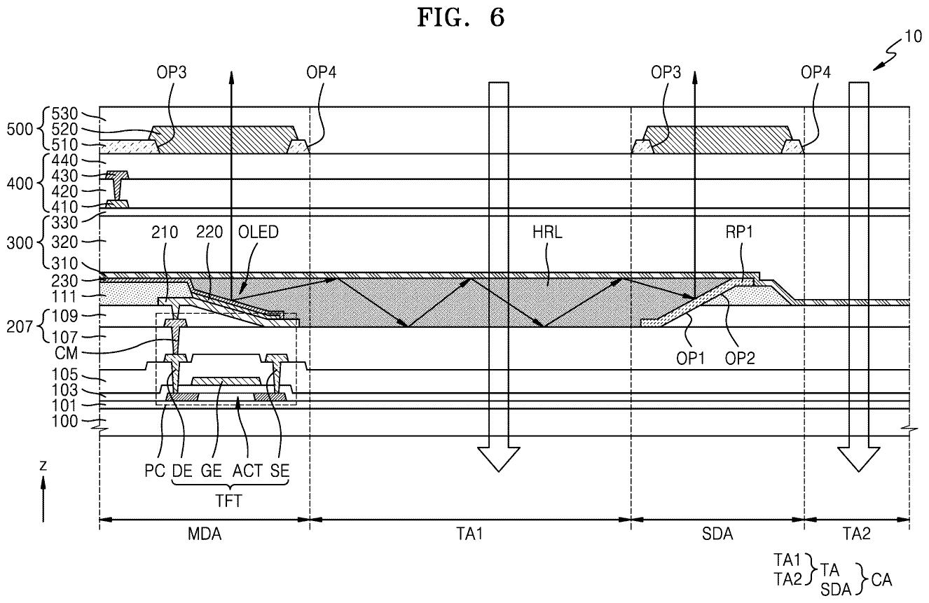

FIG. 6 is a cross-sectional view schematically illustrating a portion of the display panel 10 of FIG. 3. For example, FIG. 6 is an enlarged view of a portion of FIG. 3. Alternatively, FIG. 6 is a cross-sectional view illustrating the main display area MDA and the component area CA of the display apparatus 1 of FIG. 1.

In FIG. 6, the same reference numerals as those in FIGS. 4 and 5 indicate the same members as those in FIGS. 4 and 5, and thus, redundant descriptions thereof are omitted.

Referring to FIG. 6, an organic light-emitting diode OLED, and a pixel circuit PC corresponding to the organic light-emitting diode OLED, may be arranged in the main display area MDA. The pixel circuit PC may include a thin-film transistor TFT electrically connected to the organic light-emitting diode OLED.

A buffer layer 101 may be arranged on the substrate 100. The pixel circuit PC may be arranged on the buffer layer 101. The organic light-emitting diode OLED may be electrically connected to the pixel circuit PC.

The thin-film transistor TFT may include an active layer ACT, a gate electrode GE overlapping a channel region of the active layer ACT, a source electrode SE connected to a source region of the active layer ACT, and a drain electrode DE connected to a drain region of the active layer ACT.

A gate-insulating layer 103 may be arranged between the active layer ACT and the gate electrode GE, and an interlayer insulating layer 105 may be arranged between the gate electrode GE and the source electrode SE, and between the gate electrode GE and the drain electrode DE. A via layer 207 may be arranged on the source electrode SE and on the drain electrode DE.

The via layer 207 may be arranged on the interlayer insulating layer 105. That is, the via layer 207 may be arranged on a pixel circuit PC. For example, a plurality of via layers 207 may be provided. For example, the plurality of via layers 207 may include a first via layer 107, and a second via layer 109 arranged on the first via layer 107.

A connection electrode CM may be arranged between the first via layer 107 and the second via layer 109. The thin-film transistor TFT may be electrically connected to a pixel electrode 210 of a corresponding organic light-emitting diode OLED through the connection electrode CM. The via layer 207 may define a first opening OP1. The inner surface of the via layer 207 defining the first opening OP1 may be inclined.

The organic light-emitting diode OLED may include an overlapping structure in which the pixel electrode 210, the intermediate layer 220, and the opposite electrode 230 overlap one another. The overlapping structure may include various functional layers.

At least a portion of the pixel electrode 210 may be accommodated in the first opening OP1. The pixel electrode 210 may be arranged on an inclined surface of the via layer 207 defining the first opening OP1.

The bank layer 111 may be arranged on the pixel electrode 210, and may define a second opening OP2. The second opening OP2 may overlap the first opening OP1. The inner surface of the bank layer 111 defining the second opening OP2 may be inclined.

The intermediate layer 220 may be arranged on the pixel electrode 210. The intermediate layer 220 may be accommodated in the first opening and in the second opening OP2. The intermediate layer 220 may include an emission layer including a high molecular organic material or a low molecular organic material that emits light of a corresponding color. The intermediate layer 220 may include functional layers arranged below and/or above the emission layer.

The opposite electrode 230 may be arranged on the intermediate layer 220. The opposite electrode 230 may cover the intermediate layer 220 and the bank layer 111.

For example, in the main display area MDA, the pixel circuit PC, the connection electrode CM, and the pixel electrode 210 may overlap each other in plan view. The connection electrode CM may electrically connect the drain electrode DE to the pixel electrode 210. In a plan view, the pixel electrode 210 may overlap each of the source electrode SE and the drain electrode DE. In this structure, compared to the one or more embodiments corresponding to FIG. 5, the distance between the organic light-emitting diode OLED and the first reflective plate RP1 may be increased.

Because the inner surface of the via layer 207 defining the first opening OP1 is inclined, at least a portion of the pixel electrode 210 arranged on the via layer 207 may be inclined. Similarly, at least a portion of the intermediate layer 220 arranged on the pixel electrode 210 may be inclined.

The first reflective plate RP1 may be arranged on the bank layer 111 to be apart from the pixel electrode 210. The first reflective plate RP1 may be accommodated in each of the first opening OP1 and the second opening OP2.

Because the inner surface of the via layer 207 defining the first opening OP1 and the inner surface of the bank layer 111 defining the second opening OP2 are inclined, at least a portion of the first reflective plate RP1 arranged on the via layer 207 and the bank layer 111 may be inclined. The pixel electrode 210 and the first reflective plate RP1 may be inclined to face each other.

The high refractive index layer HRL may be arranged on the pixel electrode 210 and the first reflective plate RP1. At least a portion of the high refractive index layer HRL may be accommodated in the first opening OP1 and in the second opening OP2.

The high refractive index layer HRL may have a higher refractive index than the via layer 207 (e.g., the first via layer 107) and the encapsulation layer 300 (e.g., the first inorganic encapsulation layer 310).

The encapsulation layer 300 may be arranged on the high refractive index layer HRL. The encapsulation layer 300 may cover the opposite electrode 230, the high refractive index layer HRL, the bank layer 111, and the via layer 207. The encapsulation layer 300 may include a first inorganic encapsulation layer 310, a second inorganic encapsulation layer 330, and an organic encapsulation layer 320 therebetween.

The touch layer 400 may include touch electrodes, and the touch electrodes may have a mesh structure that at least partially surrounds the emission area of each organic light-emitting diode OLED in plan view.

The anti-reflection layer 500 may be arranged on the touch layer 400. That is, the anti-reflection layer 500 may be arranged on the encapsulation layer 300. The anti-reflection layer 500 may include a light-blocking layer 510, color filters 520, and an overcoat layer 530.

The light-blocking layer 510 may include a light-blocking material, and may define a third opening OP3 and a fourth opening OP4. The color filter 520 may be accommodated in the third opening OP3. The color filter 520 may not be arranged in the fourth opening OP4 (e.g., may be spaced from the fourth opening OP4 in plan view). The overcoat layer 530 may be arranged on the light-blocking layer 510 and on the color filter 520. At least a portion of the overcoat layer 530 may be accommodated in the fourth opening OP4.

At least a portion of the light emitted from the organic light-emitting diode OLED may be emitted outside the display panel 10 through the third opening OP3 and through the color filter 520. Therefore, a user may recognize the light in the main display area MDA.

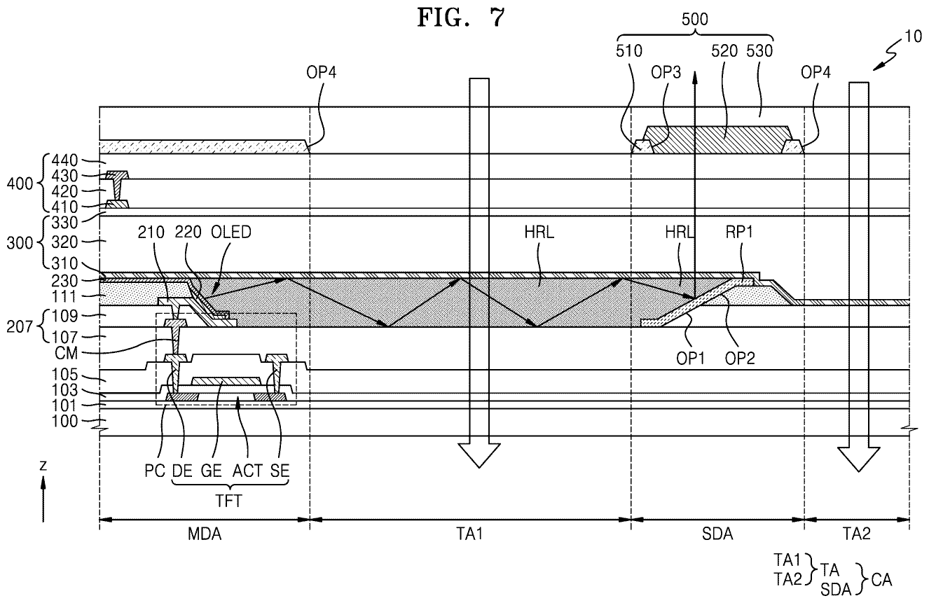

FIG. 7 is a cross-sectional view schematically illustrating a portion of the display panel 10 of FIG. 3. For example, FIG. 7 is an enlarged view of a portion of FIG. 3. Alternatively, FIG. 7 is a cross-sectional view illustrating the main display area MDA and the component area CA of the display apparatus 1 of FIG. 1.

In FIG. 7, the same reference numerals as those in FIGS. 4 and 5 indicate the same members as those in FIGS. 4 and 5, and thus, redundant descriptions thereof are omitted.

Referring to FIG. 7, an organic light-emitting diode OLED, and a pixel circuit PC corresponding to the organic light-emitting diode OLED, may be arranged in the main display area MDA. The pixel circuit PC may include a thin-film transistor TFT electrically connected to the organic light-emitting diode OLED.

A buffer layer 101 may be arranged on the substrate 100. The pixel circuit PC may be arranged on the buffer layer 101. The organic light-emitting diode OLED may be electrically connected to the pixel circuit PC.

The thin-film transistor TFT may include an active layer ACT, a gate electrode GE overlapping a channel region of the active layer ACT, a source electrode SE connected to a source region of the active layer ACT, and a drain electrode DE connected to a drain region of the active layer ACT.

A gate-insulating layer 103 may be arranged between the active layer ACT and the gate electrode GE, and an interlayer insulating layer 105 may be arranged between the gate electrode GE and the source electrode SE, and between the gate electrode GE and the drain electrode DE. A via layer 207 may be arranged on the source electrode SE and on the drain electrode DE.

The via layer 207 may be arranged on the interlayer insulating layer 105. That is, the via layer 207 may be arranged on a pixel circuit PC. For example, a plurality of via layers 207 may be provided. For example, the plurality of via layers 207 may include a first via layer 107 and a second via layer 109 arranged on the first via layer 107.

A connection electrode CM may be arranged between the first via layer 107 and the second via layer 109. The thin-film transistor TFT may be electrically connected to a pixel electrode 210 of a corresponding organic light-emitting diode OLED through the connection electrode CM. The via layer 207 may define a first opening OP1. The inner surface of the via layer 207 defining the first opening OP1 may be inclined.

The organic light-emitting diode OLED may include an overlapping structure in which the pixel electrode 210, the intermediate layer 220, and the opposite electrode 230 overlap one another. The overlapping structure may include various functional layers.

At least a portion of the pixel electrode 210 may be accommodated in the first opening OP1. The pixel electrode 210 may be arranged on an inclined surface of the via layer 207 defining the first opening OP1.

The bank layer 111 may be arranged on the pixel electrode 210, and may define a second opening OP2. The second opening OP2 may overlap the first opening OP1. The inner surface of the bank layer 111 defining the second opening OP2 may be inclined.

The intermediate layer 220 may be arranged on the pixel electrode 210. The intermediate layer 220 may be accommodated in the first opening and in the second opening OP2. The intermediate layer 220 may include an emission layer including a high molecular organic material or a low molecular organic material that emits light of a corresponding color. The intermediate layer 220 may include functional layers arranged below and/or above the emission layer.

The opposite electrode 230 may be arranged on the intermediate layer 220. The opposite electrode 230 may cover the intermediate layer 220 and the bank layer 111.

For example, in the main display area MDA, the pixel circuit PC, the connection electrode CM, and the pixel electrode 210 may overlap each other in plan view. The connection electrode CM may electrically connect the drain electrode DE to the pixel electrode 210. In a plan view, the pixel electrode 210 may overlap the drain electrode DE. In addition, in plan view, the pixel electrode 210 may be apart from the source electrode SE (e.g., the pixel electrode 210 may not overlap the source electrode SE).

In this structure, compared to the one or more embodiments corresponding to FIGS. 5 and 6, the lengths of the pixel electrode 210 and the intermediate layer 220 may decrease, and the inclination angles of the pixel electrode 210 and the intermediate layer 220 may increase. Therefore, when at least a portion of the light emitted from the organic light-emitting diode OLED reaches the boundary between the high refractive index layer HRL and the encapsulation layer 300, an incident angle may increase. Accordingly, the substantial total reflection phenomenon of light occurring at the boundary between the high refractive index layer HRL and the encapsulation layer 300, and the boundary between the high refractive index layer HRL and the via layer 207, may increase. Therefore, energy loss may be reduced in the process in which at least a portion of light emitted from the organic light-emitting diode OLED is transmitted to the first reflective plate RP1.

Because the inner surface of the via layer 207 defining the first opening OP1 is inclined, at least a portion of the pixel electrode 210 arranged on the via layer 207 may be inclined. Similarly, at least a portion of the intermediate layer 220 arranged on the pixel electrode 210 may be inclined.

The first reflective plate RP1 may be arranged on the bank layer 111 to be apart from the pixel electrode 210. The first reflective plate RP1 may be accommodated in each of the first opening OP1 and the second opening OP2.

Because the inner surface of the via layer 207 defining the first opening OP1 and the inner surface of the bank layer 111 defining the second opening OP2 are inclined, at least a portion of the first reflective plate RP1 arranged on the via layer 207 and the bank layer 111 may be inclined. The pixel electrode 210 and the first reflective plate RP1 may be inclined to face each other.

The high refractive index layer HRL may be arranged on the pixel electrode 210 and the first reflective plate RP1. At least a portion of the high refractive index layer HRL may be accommodated in the first opening OP1 and in the second opening OP2.

The high refractive index layer HRL may have a higher refractive index than the via layer 207 (e.g., the first via layer 107) and the encapsulation layer 300 (e.g., the first inorganic encapsulation layer 310).

The encapsulation layer 300 may be arranged on the high refractive index layer HRL. The encapsulation layer 300 may cover the opposite electrode 230, the high refractive index layer HRL, the bank layer 111, and the via layer 207. The encapsulation layer 300 may include a first inorganic encapsulation layer 310, a second inorganic encapsulation layer 330, and an organic encapsulation layer 320 therebetween.

The touch layer 400 may include touch electrodes, and the touch electrodes may have a mesh structure that at least partially surrounds the emission area of each organic light-emitting diode OLED in plan view.

The anti-reflection layer 500 may be arranged on the touch layer 400. That is, the anti-reflection layer 500 may be arranged on the encapsulation layer 300. The anti-reflection layer 500 may include a light-blocking layer 510, color filters 520, and an overcoat layer 530.

The light-blocking layer 510 may include a light-blocking material, and may define a third opening OP3 and a fourth opening OP4. The color filter 520 may be accommodated in the third opening OP3. The color filter 520 may be spaced from the fourth opening OP4 in plan view OP4. The overcoat layer 530 may be arranged on the light-blocking layer 510 and on the color filter 520. At least a portion of the overcoat layer 530 may be accommodated in the fourth opening OP4.

The third opening OP3 may be arranged in the sub-display area SDA. In a plan view, the third opening OP3 may overlap the first reflective plate RP1. In this structure, the color filter 520 may be arranged in the sub-display area SDA. In a plan view, the color filter 520 may overlap the first reflective plate RP1.

The fourth opening OP4 may be arranged in the transmissive area TA. In a plan view, the fourth opening OP4 may not overlap each of the organic light-emitting diode OLED and the first reflective plate RP1. For example, a plurality of fourth openings OP4 may be provided. The plurality of fourth openings OP4 may be arranged in the first transmissive area TA1 and in the second transmissive area TA2.

The light-blocking layer 510 may overlap the main display area MDA. The light-blocking layer 510 may overlap the organic light-emitting diode OLED. For example, in plan view, the light-blocking layer 510 may overlap the pixel electrode 210. Light emitted from the organic light-emitting diode OLED may not pass through the light-blocking layer 510.

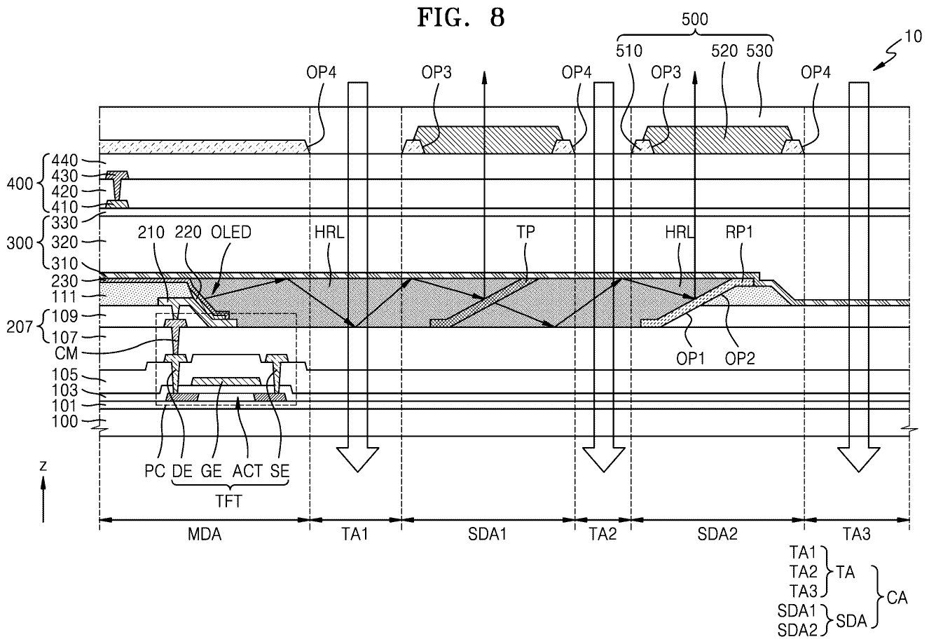

FIG. 8 is a cross-sectional view schematically illustrating a portion of the display panel 10 of FIG. 3. For example, FIG. 8 is an enlarged view of a portion of FIG. 3. Alternatively, FIG. 8 is a cross-sectional view illustrating the main display area MDA and the component area CA of the display apparatus 1 of FIG. 1.

In FIG. 8, the same reference numerals as those in FIGS. 4 and 5 indicate the same members as those in FIGS. 4 and 5, and thus, redundant descriptions thereof are omitted.

Referring to FIG. 8, an organic light-emitting diode OLED, and a pixel circuit PC corresponding to the organic light-emitting diode OLED, may be arranged in the main display area MDA. The pixel circuit PC may include a thin-film transistor TFT electrically connected to the organic light-emitting diode OLED.

A buffer layer 101 may be arranged on the substrate 100. The pixel circuit PC may be arranged on the buffer layer 101. The organic light-emitting diode OLED may be electrically connected to the pixel circuit PC.

The thin-film transistor TFT may include an active layer ACT, a gate electrode GE overlapping a channel region of the active layer ACT, a source electrode SE connected to a source region of the active layer ACT, and a drain electrode DE connected to a drain region of the active layer ACT.

A gate-insulating layer 103 may be arranged between the active layer ACT and the gate electrode GE, and an interlayer insulating layer 105 may be arranged between the gate electrode GE and the source electrode SE, and between the gate electrode GE and the drain electrode DE. A via layer 207 may be arranged on the source electrode SE and on the drain electrode DE.

The via layer 207 may be arranged on the interlayer insulating layer 105. That is, the via layer 207 may be arranged on a pixel circuit PC. For example, a plurality of via layers 207 may be provided. For example, the plurality of via layers 207 may include a first via layer 107 and a second via layer 109 arranged on the first via layer 107.

A connection electrode CM may be arranged between the first via layer 107 and the second via layer 109. The thin-film transistor TFT may be electrically connected to a pixel electrode 210 of a corresponding organic light-emitting diode OLED through the connection electrode CM. The via layer 207 may define a first opening OP1. The inner surface of the via layer 207 defining the first opening OP1 may be inclined.

The organic light-emitting diode OLED may include an overlapping structure in which the pixel electrode 210, the intermediate layer 220, and the opposite electrode 230 overlap one another. The overlapping structure may include various functional layers.

At least a portion of the pixel electrode 210 may be accommodated in the first opening OP1. The pixel electrode 210 may be arranged on an inclined surface of the via layer 207 defining the first opening OP1.

The bank layer 111 may be arranged on the pixel electrode 210, and may define a second opening OP2. The second opening OP2 may overlap the first opening OP1. The inner surface of the bank layer 111 defining the second opening OP2 may be inclined.

The intermediate layer 220 may be arranged on the pixel electrode 210. The intermediate layer 220 may be accommodated in the first opening and in the second opening OP2. The intermediate layer 220 may include an emission layer including a high molecular organic material or a low molecular organic material that emits light of a corresponding color. The intermediate layer 220 may include functional layers arranged below and/or above the emission layer.

The opposite electrode 230 may be arranged on the intermediate layer 220. The opposite electrode 230 may cover the intermediate layer 220 and the bank layer 111.

For example, in the main display area MDA, the pixel circuit PC, the connection electrode CM, and the pixel electrode 210 may overlap each other in plan view. The connection electrode CM may electrically connect the drain electrode DE to the pixel electrode 210.

Because the inner surface of the via layer 207 defining the first opening OP1 is inclined, at least a portion of the pixel electrode 210 arranged on the via layer 207 may be inclined. Similarly, at least a portion of the intermediate layer 220 arranged on the pixel electrode 210 may be inclined.

The first reflective plate RP1 may be arranged on the bank layer 111 to be apart from the pixel electrode 210. The first reflective plate RP1 may be accommodated in each of the first opening OP1 and the second opening OP2.

Because the inner surface of the via layer 207 defining the first opening OP1 and the inner surface of the bank layer 111 defining the second opening OP2 are inclined, at least a portion of the first reflective plate RP1 arranged on the via layer 207 and the bank layer 111 may be inclined. The pixel electrode 210 and the first reflective plate RP1 may be inclined to face each other.

The high refractive index layer HRL may be arranged on the pixel electrode 210 and the first reflective plate RP1. At least a portion of the high refractive index layer HRL may be accommodated in the first opening OP1 and in the second opening OP2.

The high refractive index layer HRL may have a higher refractive index than the via layer 207 (e.g., the first via layer 107) and the encapsulation layer 300 (e.g., the first inorganic encapsulation layer 310).

A transflective plate TP may be arranged between the pixel electrode 210 and the first reflective plate RP1. At least a portion of the transflective plate TP may be accommodated in the first opening OP1. The transflective plate TP may be accommodated in the first opening OP1 and in the second opening OP2. The transflective plate TP may be arranged inside the high refractive index layer HRL. The transflective plate TP may be inclined to face the pixel electrode 210. The transflective plate TP may be arranged so that at least a portion thereof is parallel to the first reflective plate RP1. The transflective plate TP may reflect a portion of light incident on the transflective plate TP, and may transmit the remaining portion of the light. For example, the transflective plate TP may include a transflective metal film including at least one of Li, Ca, LiF/Ca, LiF/Al, Al, Mg, Ag, Ag, Mg, and/or an alloy thereof.

The encapsulation layer 300 may be arranged on the high refractive index layer HRL. The encapsulation layer 300 may cover the opposite electrode 230, the high refractive index layer HRL, the bank layer 111, and the via layer 207. The encapsulation layer 300 may include a first inorganic encapsulation layer 310, a second inorganic encapsulation layer 330, and an organic encapsulation layer 320 therebetween.

The touch layer 400 may include touch electrodes, and the touch electrodes may have a mesh structure that at least partially surrounds the emission area of each organic light-emitting diode OLED in plan view.

The anti-reflection layer 500 may be arranged on the touch layer 400. That is, the anti-reflection layer 500 may be arranged on the encapsulation layer 300. The anti-reflection layer 500 may include a light-blocking layer 510, color filters 520, and an overcoat layer 530.

The light-blocking layer 510 may include a light-blocking material, and may define a third opening OP3 and a fourth opening OP4. The color filter 520 may be accommodated in the third opening OP3. The color filter 520 may be spaced from the fourth opening OP4 in plan view OP4. The overcoat layer 530 may be arranged on the light-blocking layer 510 and on the color filter 520. At least a portion of the overcoat layer 530 may be accommodated in the fourth opening OP4.

A plurality of sub-display areas SDA may be provided. For example, the plurality of sub-display areas SDA may include a first sub-display area SDA1 and a second sub-display area SDA2. A plurality of transmissive areas TA may be provided. For example, the plurality of transmissive areas TA may include a first transmissive area TA1, a second transmissive area TA2, and a third transmissive area TA3.

The main display area MDA, the first transmissive area TA1, the first sub-display area SDA1, the second transmissive area TA2, the second sub-display area SDA2, and the third transmissive area TA3 may be sequentially arranged. The first transmissive area TA1 may be arranged between the main display area MDA and the first sub-display area SDA1. The first sub-display area SDA1 may be arranged between the first transmissive area TA1 and the second transmissive area TA2. The second transmissive area TA2 may be arranged between the first sub-display area SDA1 and the second sub-display area SDA2. The second sub-display area SDA2 may be arranged between the second transmissive area TA2 and the third transmissive area TA3.

A plurality of third openings OP3 may be provided. The plurality of third openings OP3 may be arranged to correspond to the plurality of sub-display areas SDA. For example, the plurality of third openings OP3 may be arranged in the first sub-display area SDA1 and in the second sub-display area SDA2. In a plan view, at least one of the third openings OP3 may overlap the transflective plate TP. In addition, in plan view, at least one of the third openings OP3 may overlap the first reflective plate RP1.

In this structure, a plurality of color filters 520 may be provided. The plurality of color filters 520 may be arranged in the plurality of sub-display areas SDA. For example, the plurality of color filters 520 may be arranged in the first sub-display area SDA1 and in the second sub-display area SDA2. In a plan view, at least one of the color filters 520 may overlap the transflective plate TP. In addition, in plan view, at least one of the color filters 520 may overlap the first reflective plate RP1.

The fourth opening OP4 may be arranged in the transmissive area TA. In a plan view, the fourth opening OP4 may not overlap each of the organic light-emitting diode OLED, the transflective plate TP, and the first reflective plate RP1. For example, a plurality of fourth openings OP4 may be provided. The plurality of fourth openings OP4 may be arranged in the first transmissive area TA1, the second transmissive area TA2, and the third transmissive area TP3.

At least a portion of the light emitted from the organic light-emitting diode OLED may be substantially totally reflected at the boundary between the high refractive index layer HRL and the encapsulation layer 300, and at the boundary between the high refractive index layer HRL and the via layer 207, and may be transmitted to the transflective plate TP.

At least a portion of the light transmitted to the transflective plate TP may be reflected by the transflective plate TP, and may be emitted to the outside through the third opening OP3 and through the color filter 520. In addition, at least a portion of the light transmitted to the transflective plate TP may pass through the transflective plate TP, and may be transmitted to the first reflective plate RP1. At least a portion of the light transmitted to the first reflective plate RP1 may be reflected by the first reflective plate RP1, and may be emitted to the outside through the third opening OP3 and through the color filter 520. Therefore, the user may view the light in the sub-display area SDA.

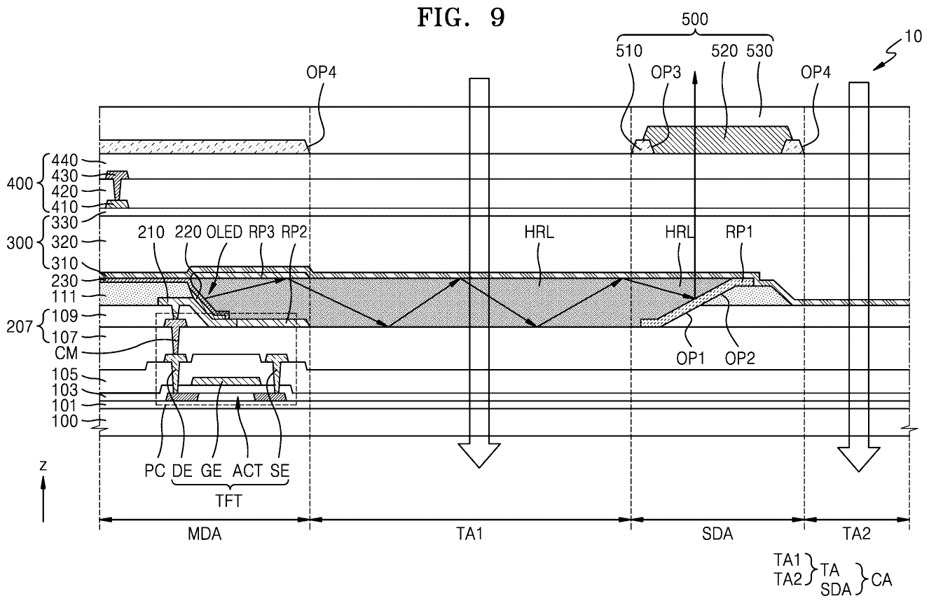

FIG. 9 is a cross-sectional view schematically illustrating a portion of the display panel 10 of FIG. 3. For example, FIG. 9 is an enlarged view of a portion of FIG. 3. Alternatively, FIG. 9 is a cross-sectional view illustrating the main display area MDA and the component area CA of the display apparatus 1 of FIG. 1.

In FIG. 9, the same reference numerals as those in FIGS. 4 and 5 indicate the same members as those in FIGS. 4 and 5, and thus, redundant descriptions thereof are omitted.

Referring to FIG. 9, an organic light-emitting diode OLED, and a pixel circuit PC corresponding to the organic light-emitting diode OLED, may be arranged in the main display area MDA. The pixel circuit PC may include a thin-film transistor TFT electrically connected to the organic light-emitting diode OLED.

A buffer layer 101 may be arranged on the substrate 100. The pixel circuit PC may be arranged on the buffer layer 101. The organic light-emitting diode OLED may be electrically connected to the pixel circuit PC.

The thin-film transistor TFT may include an active layer ACT, a gate electrode GE overlapping a channel region of the active layer ACT, a source electrode SE connected to a source region of the active layer ACT, and a drain electrode DE connected to a drain region of the active layer ACT.

A gate-insulating layer 103 may be arranged between the active layer ACT and the gate electrode GE, and an interlayer insulating layer 105 may be arranged between the gate electrode GE and the source electrode SE, and between the gate electrode GE and the drain electrode DE. A via layer 207 may be arranged on the source electrode SE and on the drain electrode DE.

The via layer 207 may be arranged on the interlayer insulating layer 105. That is, the via layer 207 may be arranged on a pixel circuit PC. For example, a plurality of via layers 207 may be provided. For example, the plurality of via layers 207 may include a first via layer 107 and a second via layer 109 arranged on the first via layer 107.

A connection electrode CM may be arranged between the first via layer 107 and the second via layer 109. The thin-film transistor TFT may be electrically connected to a pixel electrode 210 of a corresponding organic light-emitting diode OLED through the connection electrode CM. The via layer 207 may define a first opening OP1. The inner surface of the via layer 207 defining the first opening OP1 may be inclined.

The organic light-emitting diode OLED may include an overlapping structure in which the pixel electrode 210, the intermediate layer 220, and the opposite electrode 230 overlap one another. The overlapping structure may include various functional layers.

At least a portion of the pixel electrode 210 may be accommodated in the first opening OP1. The pixel electrode 210 may be arranged on an inclined surface of the via layer 207 defining the first opening OP1.

The bank layer 111 may be arranged on the pixel electrode 210, and may define a second opening OP2. The second opening OP2 may overlap the first opening OP1. The inner surface of the bank layer 111 defining the second opening OP2 may be inclined.

The intermediate layer 220 may be arranged on the pixel electrode 210. The intermediate layer 220 may be accommodated in the first opening and in the second opening OP2. The intermediate layer 220 may include an emission layer including a high molecular organic material or a low molecular organic material that emits light of a corresponding color. The intermediate layer 220 may include functional layers arranged below and/or above the emission layer.

The opposite electrode 230 may be arranged on the intermediate layer 220. The opposite electrode 230 may cover the intermediate layer 220 and the bank layer 111.

For example, in the main display area MDA, the pixel circuit PC, the connection electrode CM, and the pixel electrode 210 may overlap each other in plan view. The connection electrode CM may electrically connect the drain electrode DE to the pixel electrode 210.

Because the inner surface of the via layer 207 defining the first opening OP1 is inclined, at least a portion of the pixel electrode 210 arranged on the via layer 207 may be inclined. Similarly, at least a portion of the intermediate layer 220 arranged on the pixel electrode 210 may be inclined.

The first reflective plate RP1 may be arranged on the bank layer 111 to be apart from the pixel electrode 210. The first reflective plate RP1 may be accommodated in each of the first opening OP1 and the second opening OP2.

Because the inner surface of the via layer 207 defining the first opening OP1 and the inner surface of the bank layer 111 defining the second opening OP2 are inclined, at least a portion of the first reflective plate RP1 arranged on the via layer 207 and the bank layer 111 may be inclined. The pixel electrode 210 and the first reflective plate RP1 may be inclined to face each other.

A second reflective plate RP2 may be arranged in the main display area MDA. The second reflective plate RP2 may be arranged on the via layer 207. For example, the second reflective plate RP2 may be arranged on the first via layer 107. The second reflective plate RP2 may be provided integrally with the pixel electrode 210. For example, the second reflective plate RP2 may extend from one end of the pixel electrode 210 toward the component area CA.

A third reflective plate RP3 may be arranged in the main display area MDA. The third reflective plate RP3 may be arranged on the high refractive index layer HRL. In a plan view, the third reflective plate RP3 may overlap the organic light-emitting diode OLED. That is, in plan view, the third reflective plate RP3 may overlap the pixel electrode 210 and the intermediate layer 220.

Light that is emitted from the organic light-emitting diode OLED may be reflected by the second reflective plate RP2 and the third reflective plate RP3, and may be transmitted to the component area CA. That is, the second reflective plate RP2 and the third reflective plate RP3 may reduce the phenomenon of energy loss in a process in which light emitted from the organic light-emitting diode OLED is transmitted to the first reflective plate RP1.

The pixel electrode 210, the first reflective plate RP1, the second reflective plate RP2, and the third reflective plate RP3 may include the same material. For example, the pixel electrode 210, the first reflective plate RP1, the second reflective plate RP2, and the third reflective plate RP3 may each include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof.

The high refractive index layer HRL may be arranged on the pixel electrode 210, the first reflective plate RP1, and the second reflective plate RP2. The high refractive index layer HRL may cover the second reflective plate RP2 in the main display area MDA. At least a portion of the high refractive index layer HRL may be accommodated in the first opening OP1 and in the second opening OP2. The high refractive index layer HRL may have a higher refractive index than the via layer 207 (e.g., the first via layer 107) and the encapsulation layer 300 (e.g., the first inorganic encapsulation layer 310).

The encapsulation layer 300 may be arranged on the high refractive index layer HRL. The encapsulation layer 300 may cover the opposite electrode 230, the third reflective plate RP3, the high refractive index layer HRL, the bank layer 111, and the via layer 207 The encapsulation layer 300 may include a first inorganic encapsulation layer 310, a second inorganic encapsulation layer 330, and an organic encapsulation layer 320 therebetween.

The touch layer 400 may include touch electrodes, and the touch electrodes may have a mesh structure that at least partially surrounds the emission area of each organic light-emitting diode OLED in plan view.

The anti-reflection layer 500 may be arranged on the touch layer 400. That is, the anti-reflection layer 500 may be arranged on the encapsulation layer 300. The anti-reflection layer 500 may include a light-blocking layer 510, color filters 520, and an overcoat layer 530.

The light-blocking layer 510 may include a light-blocking material, and may define a third opening OP3 and a fourth opening OP4. The color filter 520 may be accommodated in the third opening OP3. The color filter 520 may be spaced from the fourth opening OP4 in plan view OP4. The overcoat layer 530 may be arranged on the light-blocking layer 510 and on the color filter 520. At least a portion of the overcoat layer 530 may be accommodated in the fourth opening OP4.

The third opening OP3 may be arranged in the sub-display area SDA. In a plan view, the third opening OP3 may overlap the first reflective plate RP1. In this structure, the color filter 520 may be arranged in the sub-display area SDA. In a plan view, the color filter 520 may overlap the first reflective plate RP1.

The fourth opening OP4 may be arranged in the transmissive area TA. In a plan view, the fourth opening OP4 may not overlap each of the organic light-emitting diode OLED and the first reflective plate RP1. For example, a plurality of fourth openings OP4 may be provided. The plurality of fourth openings OP4 may be arranged in the first transmissive area TA1 and in the second transmissive area TA2.

The light-blocking layer 510 may overlap the main display area MDA. The light-blocking layer 510 may overlap the organic light-emitting diode OLED. For example, in plan view, the light-blocking layer 510 may overlap the pixel electrode 210. In a plan view, the second reflective plate RP2 and the third reflective plate RP3 may each overlap the light-blocking layer 510. In a plan view, the second reflective plate RP2 and the third reflective plate RP3 may each not overlap the component area CA.

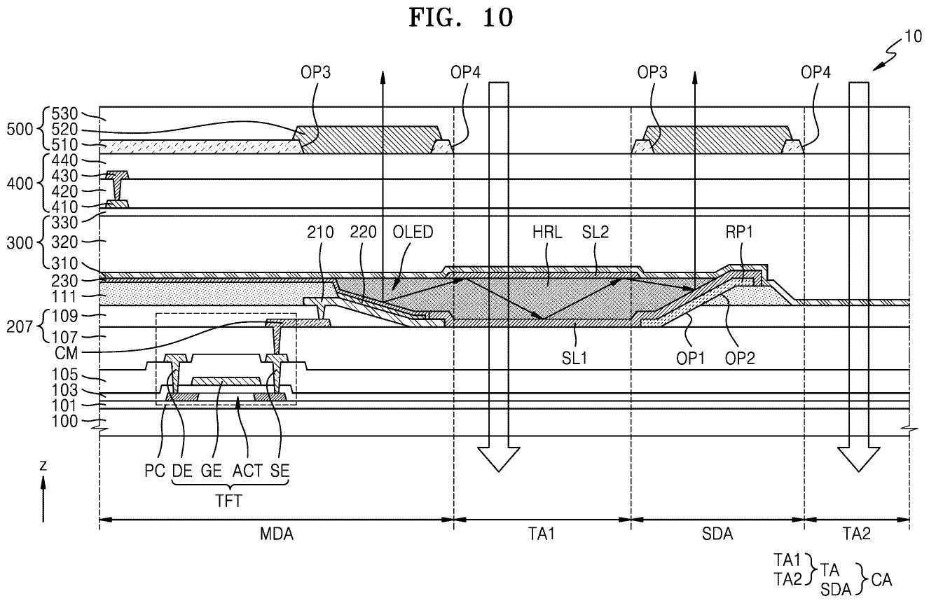

FIG. 10 is a cross-sectional view schematically illustrating a portion of the display panel 10 of FIG. 3. For example, FIG. 10 is an enlarged view of a portion of FIG. 3. Alternatively, FIG. 10 is a cross-sectional view illustrating the main display area MDA and the component area CA of the display apparatus 1 of FIG. 1.

In FIG. 10, the same reference numerals as those in FIG. 4 indicate the same members as those in FIG. 4, and thus, redundant descriptions thereof are omitted.

Referring to FIG. 10, an organic light-emitting diode OLED, and a pixel circuit PC corresponding to the organic light-emitting diode OLED, may be arranged in the main display area MDA. The pixel circuit PC may include a thin-film transistor TFT electrically connected to the organic light-emitting diode OLED.

A buffer layer 101 may be arranged on the substrate 100. The pixel circuit PC may be arranged on the buffer layer 101. That is, the pixel circuit PC including the thin-film transistor TFT may be arranged on the substrate 100.

The organic light-emitting diode OLED may be electrically connected to the pixel circuit PC. The organic light-emitting diode OLED may be electrically connected to the pixel circuit PC between the substrate 100 and the organic light-emitting diode OLED.

The thin-film transistor TFT may include an active layer ACT, a gate electrode GE overlapping a channel region of the active layer ACT, a source electrode SE connected to a source region of the active layer ACT, and a drain electrode DE connected to a drain region of the active layer ACT.

A connection electrode CM may be arranged between the first via layer 107 and the second via layer 109. The thin-film transistor TFT may be electrically connected to a pixel electrode 210 of a corresponding organic light-emitting diode OLED through the connection electrode CM.

The via layer 207 may define a first opening OP1. The first opening OP1 may be sunken from the upper surface of the via layer 207. In a plan view, the first opening OP1 may overlap the main display area MDA and the component area CA. The inner surface of the via layer 207 defining the first opening OP1 may be inclined.

The organic light-emitting diode OLED may include an overlapping structure in which the pixel electrode 210, the intermediate layer 220, and the opposite electrode 230 overlap one another. The overlapping structure may include various functional layers.

The pixel electrode 210 may be arranged on the via layer 207 and may be electrically connected to the pixel circuit PC. The pixel electrode 210 may be arranged on the second via layer 109.

The bank layer 111 may be arranged on the pixel electrode 210, and may define a second opening OP2. The bank layer 111 may be arranged on the via layer 207 and may cover an end of the pixel electrode 210. The second opening OP2 may overlap the first opening OP1. In a plan view, the second opening OP2 may overlap the main display area MDA and the component area CA. The inner surface of the bank layer 111 defining the second opening OP2 may be inclined.

The intermediate layer 220 may be arranged on the pixel electrode 210. The intermediate layer 220 may be accommodated in the first opening OP1 and in the second opening OP2. The intermediate layer 220 may include an emission layer including a high molecular organic material or a low molecular organic material that emits light of a corresponding color.

The opposite electrode 230 may be arranged on the intermediate layer 220. Because the inner surface of the via layer 207 defining the first opening OP1 is inclined, at least a portion of the pixel electrode 210 arranged on the via layer 207 may be inclined. Similarly, at least a portion of the intermediate layer 220 arranged on the pixel electrode 210 may be inclined.

The first reflective plate RP1 may be arranged on the bank layer 111 to be apart from the pixel electrode 210. Because the inner surface of the via layer 207 defining the first opening OP1 and the inner surface of the bank layer 111 defining the second opening OP2 are inclined, at least a portion of the first reflective plate RP1 arranged on the via layer 207 and the bank layer 111 may be inclined. The first reflective plate RP1 may include the same material as the pixel electrode 210.

The pixel circuit PC and the organic light-emitting diode OLED may each be arranged in the main display area MDA. The first reflective plate RP1 may be arranged in the sub-display area SDA. That is, in plan view, the first reflective plate RP1 may overlap the sub-display area SDA.

The organic light-emitting diode OLED and the first reflective plate RP1 may be apart from each other with the transmissive area TA therebetween. The pixel electrode 210 and the first reflective plate RP1 may be inclined to face each other.

A first auxiliary layer SL1 may be arranged on the via layer 207. The first auxiliary layer SL1 may extend from the opposite electrode 230 toward the component area CA. The first auxiliary layer SL1 may be arranged across the entire main display area MDA, the transmissive area TA, and the auxiliary display area SDA.

The high refractive index layer HRL may be arranged on the pixel electrode 210, the first reflective plate RP1, and the first auxiliary layer SL1. At least a portion of the high refractive index layer HRL may be accommodated in the first opening OP1 and in the second opening OP2. The high refractive index layer HRL may be arranged between the organic light-emitting diode OLED and the first reflective plate RP1 and may fill the first opening OP1 and the second opening OP2.

A second auxiliary layer SL2 may be arranged on the high refractive index layer HRL. The second auxiliary layer SL2 may be arranged in the component area CA. For example, the second auxiliary layer SL2 may be arranged in the transmissive area TA (e.g., the first transmissive area TA1). The first auxiliary layer SL1 and the second auxiliary layer SL2 may each include a transparent material. The first auxiliary layer SL1 and the second auxiliary layer SL2 may each include the same material as the opposite electrode 230. By the first auxiliary layer SL1 and the second auxiliary layer SL2, the substantial total reflection phenomenon of light in the transmissive area TA (e.g., the first transmissive area TA1) may be enhanced.

The encapsulation layer 300 may be arranged on the high refractive index layer HRL. The encapsulation layer 300 may cover the opposite electrode 230, the second auxiliary layer SL2, the high refractive index layer HRL, the bank layer 111, and the via layer 207. The encapsulation layer 300 may include a first inorganic encapsulation layer 310, a second inorganic encapsulation layer 330, and an organic encapsulation layer 320 therebetween.

The touch layer 400 may include touch electrodes, and the touch electrodes may have a mesh structure that at least partially surrounds the emission area of each organic light-emitting diode OLED in plan view.

The touch layer 400 may include a first touch electrode layer 410 on the encapsulating layer 300, a first touch-insulating layer 420 on the first touch electrode layer 410, a second touch electrode layer 430 on the first touch-insulating layer 420, and a second touch-insulating layer 440 on the second touch electrode layer 430.

The anti-reflection layer 500 may be arranged on the touch layer 400. That is, the anti-reflection layer 500 may be arranged on the encapsulation layer 300. The anti-reflection layer 500 may include a light-blocking layer 510, color filters 520, and an overcoat layer 530.

The light-blocking layer 510 may include a light-blocking material, and may define a third opening OP3 and a fourth opening OP4. The color filter 520 may be accommodated in the third opening OP3. The color filter 520 may be spaced from the fourth opening OP4 in plan view OP4. The overcoat layer 530 may be arranged on the light-blocking layer 510 and on the color filter 520. At least a portion of the overcoat layer 530 may be accommodated in the fourth opening OP4.

A plurality of third openings OP3 may be provided. The plurality of third openings OP3 may be arranged in the main display area MDA and the sub-display area SDA. In a plan view, at least one of the third openings OP3 may overlap the organic light-emitting diode OLED. In addition, at least one of the third openings OP3 may overlap the first reflective plate RP1 in plan view.

In this structure, a plurality of color filters 520 may be provided. The plurality of color filters 520 may be arranged in the main display area MDA and the sub-display area SDA. The color filters 520 may overlap the pixel electrode 210. In a plan view, at least one of the color filters 520 may overlap the organic light-emitting diode OLED. In addition, in plan view, at least one of the color filters 520 may overlap the first reflective plate RP1.

The fourth opening OP4 may be arranged in the transmissive area TA. In a plan view, the fourth opening OP4 may not overlap each of the organic light-emitting diode OLED and the first reflective plate RP1. For example, a plurality of fourth openings OP4 may be provided. The plurality of fourth openings OP4 may be arranged in the first transmissive area TA1 and in the second transmissive area TA2.

According to embodiments of the disclosure, the image quality of the display panel 10 and the display apparatus 1 may be improved, and the performance of the component 40 may be increased.

The aspects of the disclosure are not limited to the effects mentioned above, and other aspect snot mentioned may be clearly understood by those of ordinary skill in the art from the description of the claims.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display panel comprising:
a substrate;
a pixel circuit above the substrate, and comprising a thin-film transistor;
a via layer above the pixel circuit, and defining a first opening;
a pixel electrode inclined above the via layer, electrically connected to the pixel circuit, and having at least a portion in the first opening;
a bank layer above the pixel electrode, and defining a second opening overlapping the first opening;
a first reflective plate inclined above the bank layer, apart from the pixel electrode, facing the pixel electrode, and having at least a portion in the second opening;
a high refractive index layer above the pixel electrode and the first reflective plate, and having at least a portion in the first opening and in the second opening; and
an encapsulation layer above the high refractive index layer,
wherein the high refractive index layer has a refractive index that is greater than a refractive index of the via layer or the encapsulation layer.

2. The display panel of claim 1, wherein the via layer has an inclined surface defining the first opening, and
wherein the pixel electrode and the first reflective plate are above the inclined surface.

3. The display panel of claim 1, wherein the pixel electrode is apart from the pixel circuit in plan view.

4. The display panel of claim 1, further comprising an anti-reflection layer above the encapsulation layer, and comprising:
a light-blocking layer comprising a light-blocking material, and defining a third opening; and
a color filter in the third opening.

5. The display panel of claim 4, wherein the color filter overlaps the pixel electrode.

6. The display panel of claim 4, wherein the light-blocking layer overlaps the pixel electrode.

7. The display panel of claim 6, further comprising:
a second reflective plate above the via layer, and overlapping the light-blocking layer; and
a third reflective plate above the high refractive index layer, and overlapping the light-blocking layer.

8. The display panel of claim 1, further comprising a transflective plate inclined between the pixel electrode and the first reflective plate, having at least a portion in the first opening, and facing the pixel electrode.

9. The display panel of claim 1, further comprising:
an intermediate layer above the pixel electrode;
an opposite electrode above the intermediate layer;
a first auxiliary layer above the via layer, extending from the opposite electrode, and comprising a transparent material; and
a second auxiliary layer above the high refractive index layer, and comprising a transparent material.

10. The display panel of claim 9, wherein the opposite electrode, the first auxiliary layer, and the second auxiliary layer comprise a same material.

11. A display apparatus comprising:
a display panel comprising:
a main display area;
a component area;
a substrate;
a pixel circuit above the substrate, and comprising a thin-film transistor;
a via layer above the pixel circuit, and defining a first opening;
a pixel electrode inclined above the via layer, electrically connected to the pixel circuit, and having at least a portion in the first opening;
a bank layer above the pixel electrode, and defining a second opening overlapping the first opening;
a first reflective plate inclined above the bank layer, apart from the pixel electrode, having at least a portion in the second opening, facing the pixel electrode, and in the component area;
a high refractive index layer above the pixel electrode and the first reflective plate, and having at least a portion in the first opening and in the second opening; and
an encapsulation layer above the high refractive index layer; and
a component below a back surface of the display panel, and overlapping the component area,
wherein the high refractive index layer has a refractive index that is greater than a refractive index of the via layer or the encapsulation layer.

12. The display apparatus of claim 11, wherein the via layer has an inclined surface defining the first opening, and
wherein the pixel electrode and the first reflective plate are above the inclined surface.

13. The display apparatus of claim 11, wherein the pixel electrode is apart from the pixel circuit in plan view.

14. The display apparatus of claim 11, further comprising an anti-reflection layer above the encapsulation layer, and comprising:
a light-blocking layer comprising a light-blocking material, and defining a third opening; and
a color filter in the third opening.

15. The display apparatus of claim 14, wherein the color filter overlaps the pixel electrode.

16. The display apparatus of claim 14, wherein the light-blocking layer overlaps the pixel electrode.

17. The display apparatus of claim 16, further comprising:
a second reflective plate above the via layer, and overlapping the light-blocking layer; and
a third reflective plate above the high refractive index layer, and overlapping the light-blocking layer.

18. The display apparatus of claim 11, further comprising a transflective plate inclined between the pixel electrode and the first reflective plate, having at least a portion in the first opening, and facing the pixel electrode.

19. The display apparatus of claim 11, further comprising:
an intermediate layer above the pixel electrode;
an opposite electrode above the intermediate layer;
a first auxiliary layer above the via layer, extending from the opposite electrode, and comprising a transparent material; and
a second auxiliary layer above the high refractive index layer, and comprising a transparent material.

20. The display apparatus of claim 19, wherein the opposite electrode, the first auxiliary layer, and the second auxiliary layer comprise a same material.

21. An electronic device comprising a display panel comprising:
a substrate;
a pixel circuit above the substrate, and comprising a thin-film transistor;
a via layer above the pixel circuit, and defining a first opening;
a pixel electrode inclined above the via layer, electrically connected to the pixel circuit, and having at least a portion in the first opening;
a bank layer above the pixel electrode, and defining a second opening overlapping the first opening;
a first reflective plate inclined above the bank layer, apart from the pixel electrode, facing the pixel electrode, and having at least a portion in the second opening;
a high refractive index layer above the pixel electrode and the first reflective plate, and having at least a portion in the first opening and in the second opening; and
an encapsulation layer above the high refractive index layer,
wherein the high refractive index layer has a refractive index that is greater than a refractive index of the via layer or the encapsulation layer.

22. The electronic device of claim 21, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
